(19) United States
(12) Patent Application Publication
(10) Pub. No.: US 2025/0159988 A1
(43) Pub. Date: May 15, 2025

(54) ARRAY SUBSTRATE AND DISPLAY

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Chunping LONG, Beijing (CN); Jianbo XIAN, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/835,668

(22) PCT Filed: Feb. 15, 2023
(86) PCT No.: PCT/CN2023/076166

§ 371 Date: Aug. 2, 2024

(30) Foreign Application Priority Data
Feb. 16, 2022 (CN) 202210142848.2

(51) Int. Cl. H10D 86/40; H10D 86/60

(52) U.S. Cl. CPC H10D 86/441; H10D 86/471; H10D 86/60

(57) ABSTRACT

An array substrate and a display. A peripheral region of the array substrate includes a data selector circuit. The data selector circuit includes a plurality of selection driving transistors arranged in a row direction and a column direction, and each selection driving transistor includes a semiconductor layer, a source electrode and a drain electrode. The source electrode is connected to the semiconductor layer through source via holes, and the drain electrode is connected to the semiconductor layer through drain via holes. A minimum distance between the channel region and an edge of the source via hole furthest from the channel region is greater than a minimum distance between the channel region and an outer edge of the source electrode. An acute included angle is formed between the row direction and a line connecting centers of the source via hole and the drain via hole.

### CROSS-REFERENCE TO RELATED APPLICATION(S)

This patent application claims the priority of China Patent Application No. 202210142848.2, filed Feb. 16, 2022, which is incorporated herein by reference in its entirety as part of this application.

### TECHNICAL FIELD

At least one embodiment of the present disclosure relates to an array substrate and a display.

### BACKGROUND

Currently widely used display devices include thin film transistor liquid crystal display (TFT-LCD), active matrix organic light emitting diodes (AMOLED), etc., and more and more displays develop towards high resolution to provide better use experience for users.

### SUMMARY

At least one embodiment of the present disclosure relates to an array substrate and a display device.

An embodiment of the disclosure provides an array substrate comprising a display region and a peripheral region surrounding the display region, the peripheral region comprising a data selector circuit configured to provide a data signal to a data line, the data selector circuit comprising a plurality of selection driving transistors arranged in a row direction and a column direction, wherein each of the selection driving transistors comprises a semiconductor layer, a source electrode and a drain electrode, the source electrode and the drain electrode both are strip-shaped, the source electrode and the drain electrode both extends in the column direction, a portion of the semiconductor layer between the source electrode and the drain electrode is formed as a channel region, the source electrode is connected to the semiconductor layer through a plurality of source via holes on a side of the source electrode away from the channel region, the drain electrode is connected to the semiconductor layer through a plurality of drain via holes on a side of the drain electrode away from the channel region, a minimum distance between the channel region and an edge of the source via hole furthest from the channel region is greater than a minimum distance between the channel region and a portion of an outer edge of the source electrode between two source via holes, and a minimum distance between the channel region and an edge of the drain via hole furthest from the channel region is greater than a minimum distance between the channel region and a portion of an outer edge of the drain electrode between two drain via holes, an acute included angle is formed between the row direction and a line connecting centers of any one of the source via holes and any one of the drain via holes.

In the array substrate according to an embodiment of the disclosure, an included angle between the row direction and a line connecting centers of any one of source via holes and one drain via hole closest thereto of a same selection driving transistor is in a range from 35 degrees to 55 degrees.

In the array substrate according to an embodiment of the disclosure, points of a plurality of source via holes of a same selection driving transistor away from the channel region are located on a first straight line, points of a plurality of drain via holes of the same selection driving transistor away from the channel region are located on a second straight line, and the first straight line is approximately parallel to the second straight line and is approximately parallel to the column direction, a portion of the source electrode located between adjacent source via holes and a portion of the drain electrode located between adjacent drain via holes are located between the first straight line and the second straight line, and are not overlapped with the first straight line and the second straight line.

In the array substrate according to an embodiment of the disclosure, the data selector circuit further comprises a wiring located between two adjacent selection driving transistors, the wiring extends in a zigzag manner along the column direction, the two adjacent selection driving transistors are respectively a first selection driving transistor and a second selection driving transistor, the wiring comprises a plurality of first portions closest to the channel region of the first selection driving transistor in the row direction, the wiring comprises a plurality of second parts closest to the channel region of the second selection driving transistor in the row direction, and in the column direction, the plurality of first portions and the plurality of second parts are alternately arranged, the plurality of drain via holes of the first selection driving transistor and the plurality of source via holes of the second selection driving transistor are located between the channel region of the first selection driving transistor and the channel region of the second selection driving transistor, the plurality of drain via holes of the first selection driving transistor are in one-to-one correspondence with the plurality of second portions, and a line connecting centers of each of the drain via holes and the corresponding second portion is substantially parallel to the row direction, the plurality of source via holes of the second selection driving transistor are in one-to-one correspondence with the plurality of first portions, and a line connecting centers of each of the source via holes and the corresponding first portion is substantially parallel to the row direction.

In the array substrate according to an embodiment of the disclosure, the wiring includes a plurality of vertical straight-line segments substantially parallel to the column direction and arranged at intervals along the column direction, and inclined straight-line segments connecting adjacent vertical straight-line segments at an acute angle with respect to the row direction, and at least a portion of each vertical straight-line segment is the first portion or the second portion.

In the array substrate according to an embodiment of the disclosure, any one of a width of the wiring, a width of the portion of the source electrode of the selection driving transistor between adjacent source via holes, a width of the portion of the drain electrode of the selection driving transistor between adjacent drain via holes, a diameter of the source via holes, or a diameter of the drain via holes is substantially equal to a dimension d, and 1.5 μm≤d≤4 μm.

In the array substrate according to an embodiment of the disclosure, a minimum distance between the source via hole and the wiring, and a minimum distance between the drain via hole and the wiring are approximately equal to the dimension d, respectively.

In the array substrate according to an embodiment of the disclosure, an included angle between an extending direction of the vertical straight-line segment and an extending direction of the inclined straight-line segment ranges from 35 degrees to 55 degrees, and is less than or equal to an included angle between the row direction and a line connecting centers of any one of the source via holes and one drain via hole closest thereto of a same selection driving transistor.

In the array substrate according to an embodiment of the disclosure, a number of the inclined straight-line segments included in the wiring is greater than or equal to a sum of a number of the source via holes adjacent to the wiring and a number of the drain electrode via holes.

In the array substrate according to an embodiment of the disclosure, the wiring and the source electrode and the drain electrode of the selection driving transistor are made of a same layer of metal thin film, and the metal thin film is a single-layer metal thin film or comprises a plurality of metal sub-layers.

In the array substrate according to an embodiment of the disclosure, the wiring comprises at least one of a data line connected to the source electrode or the drain electrode of the selection driving transistor or a control signal connecting line connected to a gate electrode of the selection driving transistor.

The array substrate according to an embodiment of the disclosure further comprises a common electrode located at different layers with the source electrode and the drain electrode, wherein the data selector circuit comprises a plurality of rows of selection driving transistors, and wirings between the selection driving transistors in different rows are connected to a lead made of a metal on the same layer as the common electrode.

In the array substrate according to an embodiment of the disclosure, the array substrate comprises a packaging area provided with a sealant, and the data selector circuit is disposed on an inner side of the packaging area.

In the array substrate according to an embodiment of the disclosure, the array substrate further comprises a plurality of input signal lines, each input signal line is connected to N data lines through N selection driving transistors, and N is a positive integer greater than 1.

In the array substrate according to an embodiment of the disclosure, an included angle between the row direction and a line connecting centers of one source via hole and one drain via hole with minimum distance between the channel regions of two adjacent selection driving transistors in a same row is in a range from 35 degrees to 55 degrees.

In the array substrate according to an embodiment of the disclosure, the included angle between the row direction and a line connecting centers of one source via hole and one drain via hole with minimum distance between the channel regions of two adjacent selection driving transistors in the same row is equal to an included angle between the row direction and a line connecting centers of any one of source via holes and one drain via hole closet thereto of a same selection driving transistor.

In the array substrate according to an embodiment of the disclosure, a straight line, where a line connecting centers of one source via hole and one drain via hole with minimum distance between the channel regions of two adjacent selection driving transistors in a same row is located, intersect with the inclined straight-line segment and does not intersect with the vertical straight-line segment.

In the array substrate according to an embodiment of the disclosure, the straight line, where the line connecting centers of one source via hole and one drain via hole with minimum distance between the channel regions of two adjacent selection driving transistors in a same row is located, does not intersect with the source via hole and the drain via hole of the selection driving transistor in an adjacent row, and is located between the source via hole and the drain electrode via hole of the selection driving transistor in the adjacent row.

The array substrate according to an embodiment of the disclosure further comprises a first insulating layer and a second insulating layer, wherein the selection driving transistor further comprises a gate electrode located on a side of the semiconductor layer opposite to the source electrode and the drain electrode, the first insulating layer is provided between the gate electrode and the semiconductor layer, and the second insulating layer is located between the semiconductor layer, the source electrode and the drain electrode.

In the array substrate according to an embodiment of the disclosure, a first portion of the source electrode of the selection driving transistor is in contact with a portion of a main surface of the semiconductor layer, and a second portion of the source electrode of the selection driving transistor is in contact with a side surface of the semiconductor layer; a first portion of the drain electrode of the selection driving transistor is in contact with a portion of a main surface of the semiconductor layer, a second portion of the drain electrode of the selection driving transistor is in contact with a side surface of the semiconductor layer; the second portion of the source electrode includes a first protrusion portion, the second portion of the drain electrode includes a second protrusion portion; the source via hole includes a source semi-via-hole, and the source semi-via-hole penetrates through a portion of the second insulation layer; the drain via hole includes a drain semi-via-hole, the drain semi-via-hole penetrates through a portion of the second insulating layer; the first protrusion portion is closer to the semiconductor layer than a portion of the source electrode located in the source semi-via-hole; the second protrusion portion is closer to the semiconductor layer than a portion of the drain electrode located in the drain semi-via-hole; the first protrusion portion and the second protrusion portion are respectively connected to the semiconductor layer, and a distance between the first protrusion portion and the second protrusion portion is less than a distance between the source semi-via-hole and the drain semi-via-hole.

In the array substrate according to an embodiment of the disclosure, a size of the first portion of the source electrode in the row direction is greater than a size of the second portion of the source electrode of the selection driving transistor in a direction perpendicular to the row direction and the column direction; the size of the first portion of the drain electrode in the row direction is greater than the size of the second portion of the drain electrode of the selection driving transistor in the direction perpendicular to the row direction and the column direction.

In the array substrate according to an embodiment of the disclosure, the first insulating layer has a pattern shape the same as that of the semiconductor layer.

In the array substrate according to an embodiment of the disclosure, a surface at a side of the semiconductor layer away from the gate electrode has a concave-convex structure, and at least part of a structure is conformally formed on the concave-convex structure.

In the array substrate according to an embodiment of the disclosure, the gate electrode overlaps the source electrode and the drain electrode portion, respectively, and an overlapping size of the gate electrode and the source electrode and the drain electrode is less than 1 micrometer in the row direction.

In the array substrate according to an embodiment of the disclosure, the gate electrode comprises a slope portion at its edge, and the overlapping size is greater than a size of the slope portion in the row direction.

The array substrate according to an embodiment of the disclosure further comprises a switching transistor located in the display region, wherein the switching transistor comprises a light shielding layer shielding a channel region of the switching transistor, and a gate electrode of the selection driving transistor and the light shielding layer of the display region are located on a same layer.

The array substrate according to an embodiment of the disclosure further comprises a floating metal strip located on a side, away from the semiconductor layer, of at least one of the source electrode and the drain electrode of the selection driving transistor, wherein the floating metal strip and the common electrode are located on a same layer.

In the array substrate according to an embodiment of the disclosure, the data selector circuit comprises four control signal lines extending in the row direction, the four control signal lines are respectively connected to the gate electrodes of the corresponding selection driving transistors in the plurality of selection driving transistors, and the input signal lines are connected to the source electrodes of the corresponding selection driving transistors in the plurality of selection driving transistors.

In the array substrate according to an embodiment of the disclosure, the plurality of selection driving transistors comprises a first selection driving transistor and a second selection driving transistor, the first selection driving transistor and the second selection driving transistor are respectively connected to different control signal lines, and a maximum size of the first selection driving transistor in the row direction is different from a maximum size of the second selection driving transistor in the row direction.

In the array substrate according to an embodiment of the disclosure, a material of the semiconductor layer comprises low-temperature polysilicon, the display region comprises a switching transistor, and a material of the semiconductor layer of the switching transistor comprises an oxide semiconductor material.

In the array substrate according to an embodiment of the disclosure, the selection driving transistor is a bottom gate thin film transistor, and the source electrode and the drain electrode of the selection driving transistor are located on the same layer as the gate electrode of the switching transistor and are made of the same material.

In the array substrate according to an embodiment of the disclosure, the selection driving transistor of the data selector circuit is a bottom gate thin film transistor, the switching transistor is a top gate thin film transistor, and the source electrode and the drain electrode of the selection driving transistor are located on the same layer as the gate electrode of the switching transistor and are made of the same material.

In the array substrate according to an embodiment of the disclosure, a drain electrode of the switching transistor and a source electrode of the switching transistor are different in material and located in different layers.

In the array substrate according to an embodiment of the disclosure, the material of the drain electrode of the switching transistor comprises indium tin oxide, and the material of the source electrode of the switching transistor comprises a Ti/Al/Ti laminated structure.

In the array substrate according to an embodiment of the disclosure, the source electrodes of the selection driving transistors located in different rows and located in the same column of the data selector circuit are connected to a transferring structure, the transferring structure comprises a first conductive portion, a second conductive portion, a third conductive portion, and a fourth conductive portion, and the first conductive portion and the light-shielding layer of the switching transistor are located on a same layer; the second conductive part and the gate electrode of the switching transistor are located on a same layer; the third conductive part and the source electrode of the switching transistor are located on a same layer; and the fourth conductive part and the drain electrode of the switching transistor are located on a same layer.

In the array substrate according to an embodiment of the disclosure, a pitch of the selection driving transistors of the data selector circuit in the row direction is equal to 8d.

An embodiment of the disclosure further provides a display, comprising the array substrate according to any one items as mentioned above, wherein a number of pixels per inch of the display is greater than 500.

In the display according to an embodiment of the disclosure, the number of pixels per inch of the display is greater than 1000.

In the display according to an embodiment of the disclosure, a width of the wiring, a width of the source electrode of the selection drive transistor, a width of the drain electrode of the selection drive transistor, a diameter of the source via hole, a diameter of the drain via hole each are substantially equal to a dimension d, and 1.5 μm≤d≤4 μm.

In the display according to an embodiment of the disclosure, a pitch of the selection driving transistors of the data selector circuit in the row direction is equal to 8d, PPI×8d <K1, and 0.3≤K1≤4.

In the display according to an embodiment of the disclosure, a frame height of the display is h, a number of the source via holes or the drain via holes of one of the selection driving transistors of the data selector circuit is q, a row number of the driving transistors of the data selector circuit is r, and an included angle between the row direction and a line connecting centers of any one of the source via holes and one drain via hole closest thereto of a same selection driving transistor is α, where q, r, d, and α satisfy:

$$h = {k}_{2} \times r \times ( 2 q - 1 ) \times 4 d \times tan α$$

where k₂ is a proportionality coefficient, and 0.9<k₂<1.5, 30<α<60.

In the display according to an embodiment of the disclosure, a current loss ratio R_{I_loss} of the selection driving transistor satisfies:

$${R}_{I\_loss} = cos α = \sqrt{\frac{1}{1 + \frac{{h}^{2}}{16 {k}_{2}^{2} {r}^{2} {{d}^{2} ( 2 q - 1 )}^{2}}}} ,$$

where R_{I_loss} is a current loss ratio.

### BRIEF DESCRIPTION OF DRAWINGS

In order to more clearly illustrate the technical solutions of the embodiments of the present disclosure, the accompanying drawings of the embodiments are briefly described below, and it would have been obvious that the drawings in the following description merely relate to some embodiments of the present disclosure, rather than limiting the present disclosure.

FIG. 1 is an overall layout diagram of a display panel.

FIG. 2 is a schematic diagram of a data selector circuit in a peripheral area of a display panel.

FIG. 3 is a schematic diagram of a plurality of selection driving transistors arranged in an array on an array substrate.

FIG. 4 is a schematic diagram of a selection driving transistor on an array substrate according to an embodiment of the present disclosure.

FIGS. 5A-SD are plan views of a single layer of the selection driving transistor of FIG. 4.

FIG. 5E is a laminate plan view of an active layer and a conductive pattern layer.

FIG. 6 is a cross-sectional view taken along line A1-A2 of FIG. 4.

FIG. 7A is a schematic diagram of an array substrate according to an embodiment of the present disclosure.

FIG. 7B to FIG. 7E are schematic diagrams of a single layer of the array substrate shown in FIG. 7A.

FIG. 7F is a schematic diagram of a lamination structure of the array substrate shown in FIG. 7A.

FIG. 8 is a schematic diagram of an array substrate according to an embodiment of the present disclosure.

FIG. 9 is a schematic diagram of an array substrate according to an embodiment of the present disclosure.

FIG. 10 is a schematic diagram of an array substrate according to an embodiment of the present disclosure.

FIG. 11 is a schematic diagram of an array substrate according to an embodiment of the present disclosure.

FIG. 12 is a schematic diagram of an array substrate according to an embodiment of the present disclosure.

FIG. 13 is a schematic diagram of an array substrate according to an embodiment of the present disclosure.

FIG. 14 is a schematic diagram of an array substrate according to an embodiment of the present disclosure.

FIG. 15 is a schematic diagram of an array substrate according to an embodiment of the present disclosure.

FIG. 16 is a schematic diagram of an array substrate according to an embodiment of the present disclosure.

FIG. 17A is a schematic diagram of an array substrate according to an embodiment of the present disclosure.

FIG. 17B is a schematic diagram of an array substrate according to an embodiment of the present disclosure.

FIG. 18 is a schematic diagram of an array substrate according to an embodiment of the present disclosure.

FIG. 19A is a schematic diagram of an array substrate according to an embodiment of the present disclosure.

FIG. 19B is a schematic diagram of an array substrate according to an embodiment of the present disclosure.

FIG. 19C is a schematic diagram of an array substrate according to an embodiment of the present disclosure.

FIG. 19D is a schematic diagram of an array substrate according to an embodiment of the present disclosure.

FIG. 19E is a schematic diagram of a display panel according to an embodiment of the present disclosure.

FIG. 19F is a schematic cross-sectional view of a display panel according to at least one embodiment of the present disclosure.

FIG. 20 is a schematic diagram of an array substrate according to an embodiment of the present disclosure.

FIG. 21 is a schematic diagram of a transferring structure in an array substrate according to an embodiment of the present disclosure.

FIG. 22A is a schematic diagram of a data selector circuit in an array substrate according to an embodiment of the present disclosure.

FIG. 22B is a schematic diagram of a data selector circuit in an array substrate according to an embodiment of the present disclosure.

FIG. 22C is a schematic diagram of a data selector circuit in an array substrate according to an embodiment of the present disclosure.

FIG. 23 is a schematic diagram of an array substrate according to an embodiment of the present disclosure.

FIG. 24 illustrates lengths of a channel in the cases where a line connecting centers of the source via hole and the drain via hole is obliquely arranged and arranged in parallel with respect to the row direction.

### DETAILED DESCRIPTION

In order to make the objectives, technical solutions and advantages of the embodiments of the present disclosure clearer, the technical solutions of the embodiments of the present disclosure will be clearly and completely described below with reference to the accompanying drawings of the embodiments of the present disclosure. Obviously, the described embodiments are part of the embodiments of the present disclosure, rather than all of the embodiments. All other embodiments obtained by those of ordinary skill in the art based on the described embodiments of the present disclosure without creative efforts shall fall within the protection scope of the present disclosure.

Unless otherwise defined, the technical terms or scientific terms used in the present disclosure should be the usual meanings understood by one of ordinary skill in the art to which the present disclosure belongs. The terms “first”, “second” and the like used in the present disclosure do not denote any order, quantity, or importance, but are merely used to distinguish different components. Likewise, words such as “comprise” or “include” are intended to indicate that elements or objects in front of the word encompass the elements or objects listed after the word and their equivalents, without excluding other elements or articles. Words such as “connected” or “connection” are not limited to physical or mechanical connections, but may include electrical connections, whether direct or indirect. The terms “upper”, “lower”, “left”, “right” and the like are only used to represent the relative positional relationship, and when the absolute position of the described object is changed, the relative positional relationship may also be correspondingly changed.

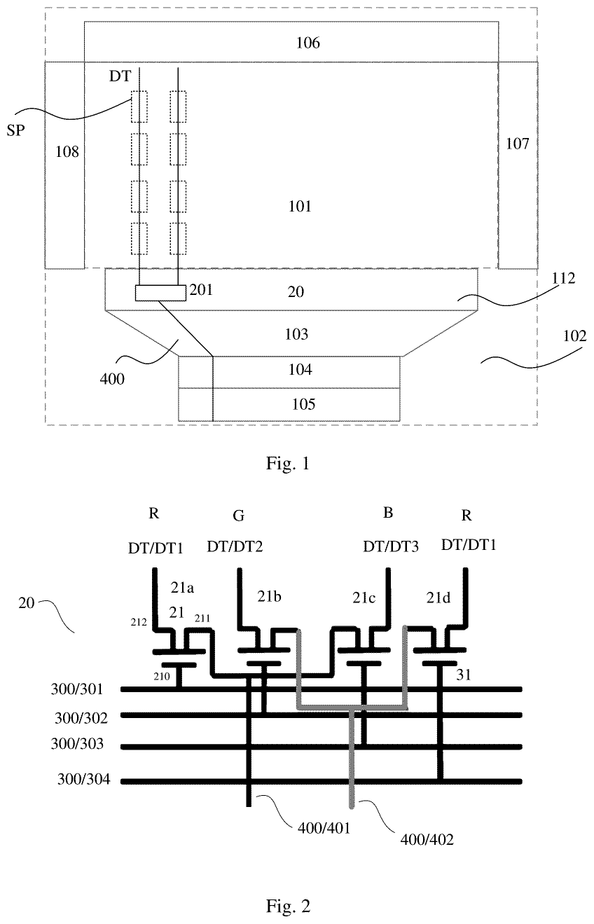

FIG. 1 is an overall layout diagram of a display panel. As shown in FIG. 1, the display panel includes a display area 101 and a peripheral area 102 surrounding the display area 101, the peripheral area 102 includes a data selector circuit 20 configured to provide a data signal to the data line DT, and the data selector circuit 20 is located in the data selector circuit arrangement area 112.

As shown in FIG. 1, the data selector circuit 20 includes a data selection unit 201, and FIG. 1 shows that two data lines DT are connected to one input signal line 400 through a data selection unit 201. In other embodiments, one input signal line 400 may also be connected to different number of data lines.

As shown in FIG. 1, the peripheral region 102 of the display panel further includes a fan-out line arrangement region 103, a test line arrangement region 104, an external circuit interface region 105, a gate driver on array (GOA) circuit region 107, and a GOA circuit region 108. Of course, the display panel may also adopt other suitable structures.

FIG. 1 further shows a sub-pixel SP. The display panel includes a plurality of sub-pixels SP that emit light of different colors. For example, the sub-pixel SP includes a sub-pixel that emits red light, a sub-pixel that emits green light, and a sub-pixel that emits blue light, but is not limited thereto, and the light-emitting color of the sub-pixel SP may be determined according to needs.

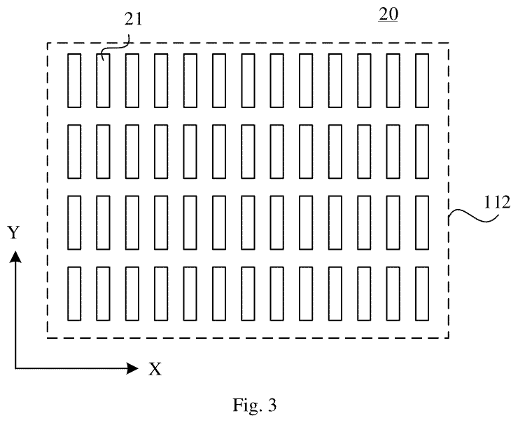

FIG. 2 is a schematic diagram of a data selector circuit in a peripheral area of a display panel. As shown in FIG. 2, the data selector circuit 20 includes four selection driving transistors 21: a selection driving transistor 21a, a selection driving transistor 21b, a selection driving transistor 21c, and a selection driving transistor 21d. As shown in FIG. 2, each of the selection driving transistors 21 includes a gate electrode 210, a source electrode 211, and a drain electrode 212.

FIG. 2 shows a row of selection driving transistors 21. Input signal lines 400 includes an input signal line 401 and an input signal line 402. Control signal lines 300 includes a control signal line 301, a control signal line 302, a control signal line 303, and a control signal line 304. Data lines DT includes a data line DT1, a data line DT2, and a data line DT3.

As shown in FIG. 2, the control signal line 300 is connected to the gate electrode 210 of the selection driving transistor 21 through the control signal connection line 31.

As shown in FIG. 2, the input signal line 401 is connected to the data line DT1 through the selection driving transistor 21a, and is connected to the data line DT3 through the selection driving transistor 21c; the input signal line 402 is connected to the data line DT2 through the selection driving transistor 21b, and is connected to the data line DT1 through the selecting the driving transistor 21d.

For example, the selection driving transistors connected to the same input signal line 400 are alternately turned on to transmit data signals to the data lines connected thereto.

As shown in FIG. 2, when the control signal line 301 is supplied with a turn-on voltage and the control signal line 303 is supplied with a turn-off voltage, the selection driving transistor 21c is turned off, the selection driving transistor 21a is turned on, and the signal on the input signal line 401 is transmitted to the data line DT1 connected to the selection driving transistor 21a; when the control signal line 301 is supplied with a turn-off voltage and the control signal line 303 is supplied with a turn-on voltage, the selection driving transistor 21c is turned on, the selection driving transistor 21a is turned off, and the signal on the input signal line 401 is transmitted to the data line DT3 connected to the selection driving transistor 21c.

As shown in FIG. 2, when the control signal line 302 is supplied with a turn-on voltage and the control signal line 304 is supplied with a turn-off voltage, the selection driving transistor 21d is turned off, the selection driving transistor 21b is turned on, and the signal on the input signal line 402 is transmitted to the data line DT2 connected to the selection driving transistor 21b; when the control signal line 302 is supplied with a turn-off voltage and the control signal line 304 is supplied with a turn-on voltage, the selection driving transistor 21d is turned on, the selection driving transistor 21b is turned off, and the signal on the input signal line 402 is transmitted to the data line DT1 connected to the selection driving transistor 21d.

FIG. 3 is a schematic diagram of a plurality of selection driving transistors arranged in an array on an array substrate. As shown in FIG. 3, the data selector circuit 20 includes a plurality of selection driving transistors 21 arranged in a row direction and a column direction. FIG. 3 shows a direction X and a direction Y, and the direction X and the direction Y intersects with each other. For example, the direction X and the direction Y are perpendicular to each other. For example, the direction X is the row direction, and the direction Y is the column direction. According to an embodiment of the present disclosure, an example, in which the direction X is the row direction, the direction Y is the column direction, and the direction X and the direction Y are perpendicular to each other, is taken for description.

FIG. 3 shows a four-row data selector circuit 20, and it should be noted that the row number and the column number of the data selector circuit 20 are not limited to FIG. 3, and may be determined according to needs.

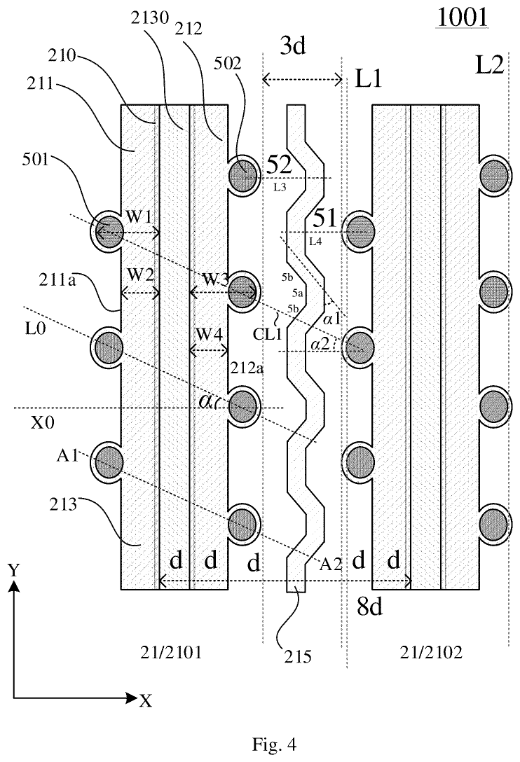

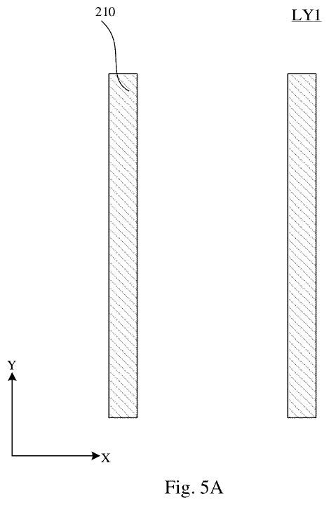

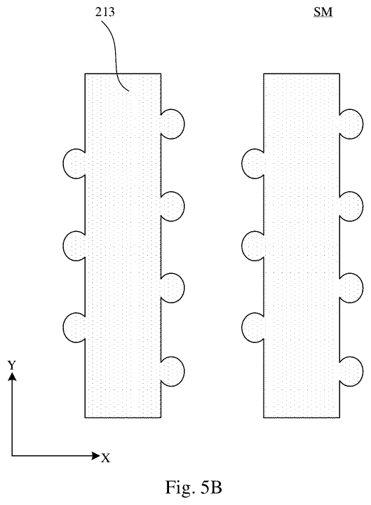

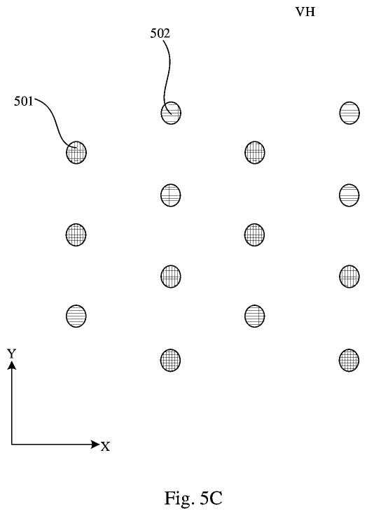

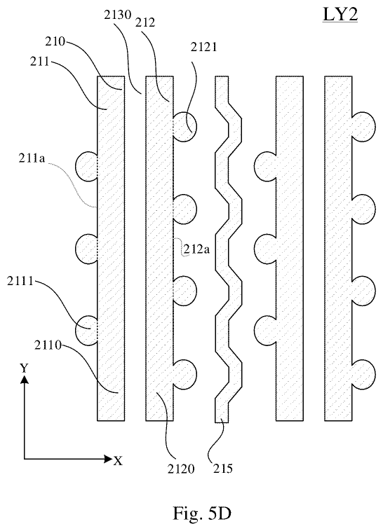

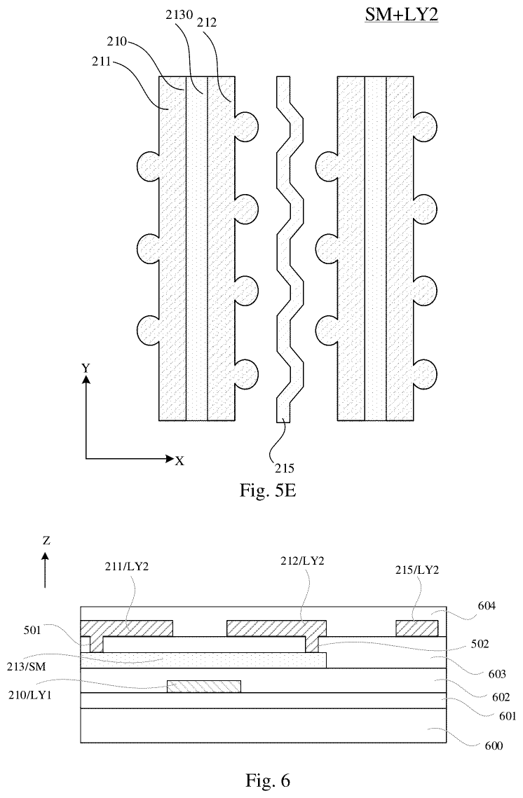

FIG. 4 is a schematic diagram of a selection driving transistor on an array substrate according to an embodiment of the present disclosure. FIGS. 5A-5D are plan views of a single layer of the selection driving transistor of FIG. 4. FIG. 5E is a laminate plan view of the active layer and the conductive pattern layer. FIG. 6 is a cross-sectional view taken along line A1-A2 of FIG. 4.

FIG. 5A shows a conductive pattern layer LY1, the conductive pattern layer LY1 includes a gate electrode 210. FIG. 5B shows an active layer SM, the active layer SM includes a semiconductor layer 213. FIG. 5C shows a via hole VH, the via hole VH includes a source via hole 501 and a drain via hole 502. FIG. 5D shows a conductive pattern layer LY2, the conductive pattern layer LY2 includes a source electrode 211, a drain electrode 212, and a wiring 215. As shown in FIG. 5E, a portion of the active layer SM between the source electrode 211 and the drain electrode 212 is a channel region 2130

FIG. 4 shows two selection driving transistors 21 located in the peripheral area of the array substrate 1001, and the two selection driving transistors 21 are located in the same row.

As shown in FIG. 4, FIG. 5A to FIG. 5D, each selection driving transistor 21 includes a semiconductor layer 213, a source electrode 211 and a drain electrode 212, the source electrode 211 and the drain electrode 212 are strip-shaped, the source electrode 211 and the drain electrode 212 both extend along a column direction Y, a portion of the semiconductor layer 213 between the source electrode 211 and the drain electrode 212 forms a channel region 2130. The source electrode 211 is connected to the semiconductor layer 213 through a plurality of source via holes 501 located on a side of the source electrode 211 away from the channel region 2130, the drain electrode 212 is connected to the semiconductor layer 213 through a plurality of drain via holes 502 located on a side of the drain electrode 212 away from the channel region 2130. The minimum distance W1 between channel region 2130 and the edge of the source via hole 501 furthest from the channel region 2130 is greater than the minimum distance W2 between the channel region 2130 and the portion 211a of the outer edge of the source electrode 211 between two source via holes 501, and the minimum distance W3 between the channel region 2130 and the edge of the drain via hole 502 furthest from the channel region 2130 is greater than the minimum distance W4 between the channel region 2130 and the portion 212a of the outer edge of the drain electrode 212 between two drain via holes 502.

For example, as shown in FIG. 4, an acute included angle α is formed between the row direction X and a line connecting centers of any one of the source via holes 501 and any one of the drain via holes 502. In FIG. 4, the straight line X0 is a straight line parallel to the row direction X.

As shown in FIG. 5D, the source electrode 211 includes a main body portion 2110 and a connecting portion 2111, the main body portion 2110 is strip-shaped, and the connecting portion 2111 is configured to be connected to the semiconductor layer 213 through the source via hole 501.

For example, as shown in FIG. 4 and FIG. 5D, the portion of the outer edge of the source electrode 211 located between the two source via holes 501 is a part of the outer edge of the main body portion 2110 of the source electrode 211.

As shown in FIG. 5D, the drain electrode 212 includes a main body portion 2120 and a connecting portion 2121, the main body portion 2120 is strip-shaped, and the connecting portion 2121 is configured to be connected to the semiconductor layer 213 through the drain via hole 502.

For example, as shown in FIG. 4 and FIG. 5D, a portion of the outer edge of the drain electrode 212 located between the two drain via holes 502 is a part of the outer edge of the main body portion 2120 of the drain electrode 212.

In the array substrate provided by the embodiments of the present disclosure, the material of the semiconductor layer 213 includes low-temperature polysilicon.

In the case that the material of the semiconductor layer 213 uses low-temperature polysilicon, the leakage current is large, an acute included angle is formed between the row direction X and a line L0 connecting centers of any source via hole 501 and any drain via hole 502 so that the off-state leakage current can be reduced.

As shown in FIG. 6, a buffer layer 601 is located on the base substrate 600, a gate electrode 210 is located on the buffer layer 601, a gate insulating layer 602 is located on the gate electrode 210, a semiconductor layer 213 is located on the gate insulating layer 602, an interlayer insulating layer 603 is located on the semiconductor layer 213, and the source electrode 211, the drain electrode 212 and the wiring 215 are all located on the interlayer insulating layer 603, and an insulating layer 604 is provided on the conductive pattern layer LY2. In FIG. 4, the base substrate and each insulating layer is treated as transparency.

In the embodiments of the present disclosure, by adjusting the positions of the source via hole 501 and the drain electrode via hole 502 to the outer sides of the source electrode 211 and the drain electrode 212, respectively, compared with the case where the source electrode via hole and the drain electrode via hole are respectively located at the inner sides of the source electrode and the drain electrode, the reliability of the transistor is improved, which is more conducive to forming a high-resolution display.

For example, as shown in FIG. 6, according to the array substrate provided by the embodiments of the present disclosure, the array substrate further comprises a gate insulating layer 602 and an interlayer insulating layer 603, the selection driving transistor 21 further comprises a gate electrode 210 located on a side of the semiconductor layer 213 opposite to the source electrode 211 and the drain electrode 212, a gate insulating layer 602 is provided between the gate electrode 210 and the semiconductor layer 213, and the interlayer insulating layer 603 is located between the semiconductor layer 213, the source electrode 211, and the drain electrode 212. In some embodiments, the gate insulating layer 602 may be referred to as a first insulating layer, and the interlayer insulating layer 603 may be referred to as a second insulating layer.

For example, as shown in FIG. 4, in the array substrate provided by the embodiments of the present disclosure, the included angle α between the row direction X and a line L0 connecting centers of any one source via hole 501 and one drain via hole 502 closest thereto in the same selection driving transistor 21 is between 35 degrees and 55 degrees. For example, the included angle α is 45 degrees.

For example, as shown in FIG. 4, in the array substrate provided by the embodiments of the present disclosure, the points of the plurality of source via holes 501 of the same selection driving transistor 21 furthest from the channel region 2130 is located on the first straight line L1, the points of the plurality of drain via holes 502 of the same selection driving transistor 21 furthest from the channel region 2130 is located on the second straight line L2, and the first straight line L1 is approximately parallel to the second straight line L2 and is approximately parallel to the column direction Y. The portion 211a of the source electrode 211 located between adjacent source via holes 501 and the portions 212a of the drain electrode 212 between two adjacent drain via holes 502 are located between the first straight line L1 and the second straight line L2, and do not overlap the first straight line L1 and the second straight line L2.

For example, as shown in FIG. 4, in the array substrate provided by the embodiments of the present disclosure, the data selector circuit 20 further includes a wiring 215 located between two adjacent selection driving transistors 21, the wiring 215 extends along the column direction in a zigzag manner. Two adjacent selection driving transistors 21 are a first selection driving transistor 2101 and a second selection driving transistor 2102, respectively. The wiring 215 includes a plurality of first portions 51 closest to the channel region 2130 of the first selection driving transistor 2101 in the row direction X, and a plurality of second portions 52 closest to the channel region 2130 of the second selection driving transistor 2102 in the row direction X. The plurality of first portions 51 and the plurality of second portions 52 are alternately arranged in the column direction Y. The plurality of drain via holes 502 of the first selection driving transistor 2101 and the plurality of source via holes 501 of the second selection driving transistor 2102 are located between the channel region 2130 of the first selection driving transistor 2101 and the channel region 2130 of the second selection driving transistor 2102. The plurality of drain via holes 502 of the first selection driving transistor 2101 correspond to the plurality of second parts 52 one by one, and a line L3 connecting centers of each drain via hole 502 and the corresponding second part 52 is approximately parallel to the row direction X, and the plurality of source via holes 501 of the second selective driving transistor 2102 correspond to the plurality of first parts 51 one by one, and a line L4 connecting centers of each source via hole 501 and the corresponding first part 51 is approximately parallel to the row direction X.

For example, as shown in FIG. 4, in the array substrate provided by the embodiments of the present disclosure, the wiring 215 includes a plurality of vertical straight-line segments 5a substantially parallel to the column direction Y and arranged at intervals along the column direction Y, and an inclined straight-line segment 5b connecting adjacent vertical straight-line segments 5a having an acute angle with respect to the row direction X, at least a portion of each vertical straight-line segment Sa is the first portion 51 or the second portion 52.

For example, as shown in FIG. 4, in the array substrate provided by the embodiments of the disclosure, the width of the wiring 215, the width of the portion 211a of the source electrode 211 of the selection driving transistor 21 located between adjacent source via holes 501, the width of the portion 212a of the drain electrode 212 of the selection driving transistor 21 between adjacent drain via holes 502, the diameter of the source via hole 501, and the diameter of the drain via hole 502 are substantially equal to a dimension d, and 1.5 μm≤d≤4 μm. For example, d is the smallest critical dimension on the array substrate of the display screen, defined as the process resolution.

For example, as shown in FIG. 4, in the array substrate provided by the embodiments of the present disclosure, the minimum distance between the source via hole 501 and the wiring 215 and the minimum distance between the drain via hole 502 and the wiring 215 are approximately equal to the dimension d, respectively. As shown in FIG. 4, the distance between two adjacent select driving transistors 21 is 3d.

For example, as shown in FIG. 4, in the array substrate provided by the embodiments of the present disclosure, the included angle α1 between the vertical straight-line segment 5a and the extending direction of the inclined straight-line segment 5b is between 35 degrees and 55 degrees, and is less than or equal to the included angle α between the row direction X and the line L0 connecting centers of any one source via hole 501 and one drain via hole 502 closest thereto of the same selection driving transistor 21.

For example, as shown in FIG. 4, in the array substrate provided by the embodiments of the present disclosure, the number of inclined straight-line segments 5b included in the wiring 215 is greater than or equal to the sum of the number of source via holes 501 and the number of drain via holes 502 adjacent to the wiring 215.

For example, as shown in FIG. 4 and FIG. 5D, in the array substrate provided by the embodiments of the present disclosure, the wiring 215 and the source electrode 211 and the drain electrode 212 of the selection driving transistor 21 are formed of the same metal thin film. For example, the metal thin film is a single-layer metal thin film or comprises a plurality of metal sub-layers.

For example, as shown in FIG. 4, in the array substrate provided by the embodiments of the present disclosure, the wiring 215 includes at least one of a data line DT connected to the source electrode 211 or the drain electrode 212 of the selection driving transistor 21 or a control signal connection line 31 (referring to FIG. 2) connected to the gate electrode 210 of the selection driving transistor 21.

As shown in FIG. 4, the source via hole 501 and the drain via hole 502 are away from the channel 2130, and the wiring 215 is of sawtooth or zigzag shape. Because the high PPI needs to be provided with more selection driving transistors and smaller line width and spacing, the positions of the source via hole 501 and the drain via hole 502 and the shape of the wiring 215 are adjusted.

For example, as shown in FIG. 4, in the array substrate provided by the embodiments of the present disclosure, the included angle 2 between the row direction X and a line CL1 connecting centers of one source via hole 501 and one drain via hole 502 which are located between the channel regions 2130 of two adjacent selection driving transistors in the same row and closest to each other is between 35 degrees and 55 degrees.

For example, as shown in FIG. 4, in the array substrate provided by the embodiments of the present disclosure, the included angle α2 between the row direction X and a line CL1 connecting centers of one source via hole 501 and one drain via hole 502 which are located between the channel regions 2130 of two adjacent selection driving transistors in the same row and closest to each other is equal to the included angle α between the row direction X and the line L0 connecting centers of any one source via hole 501 and one drain via hole 502 closest thereto of the same selection driving transistor 21.

For example, as shown in FIG. 4, in the array substrate provided by the embodiments of the present disclosure, a straight line, where the line CL1 connecting centers of one source via hole 501 and one drain via hole 502 which are located between the channel regions 2130 of two adjacent selection driving transistors in the same row and closest to each other is located, intersects with the inclined straight-line segment 5b and does not intersect the vertical straight-line segment 5a.

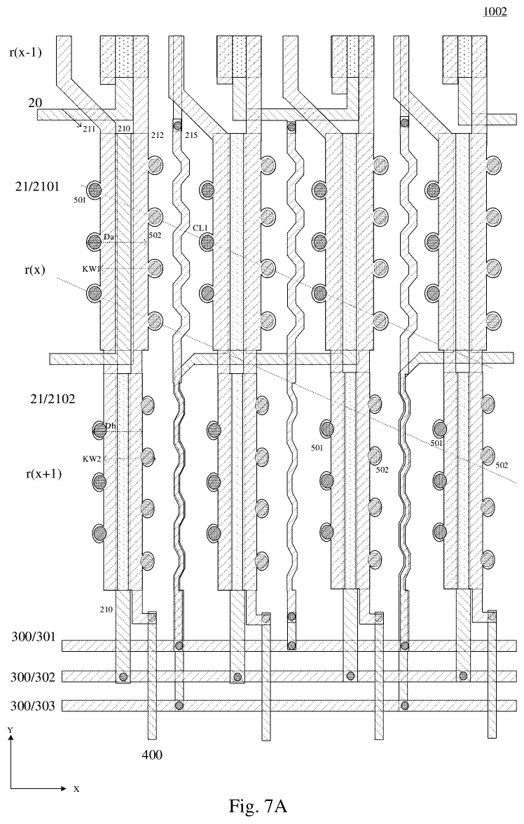

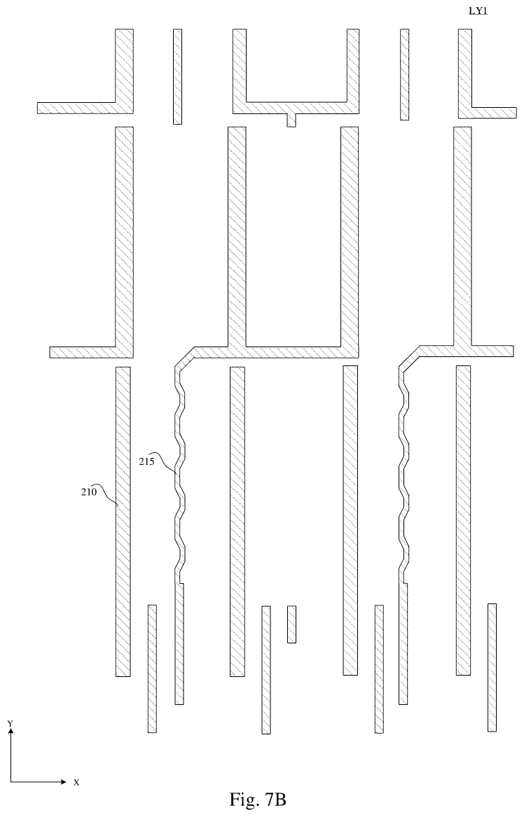

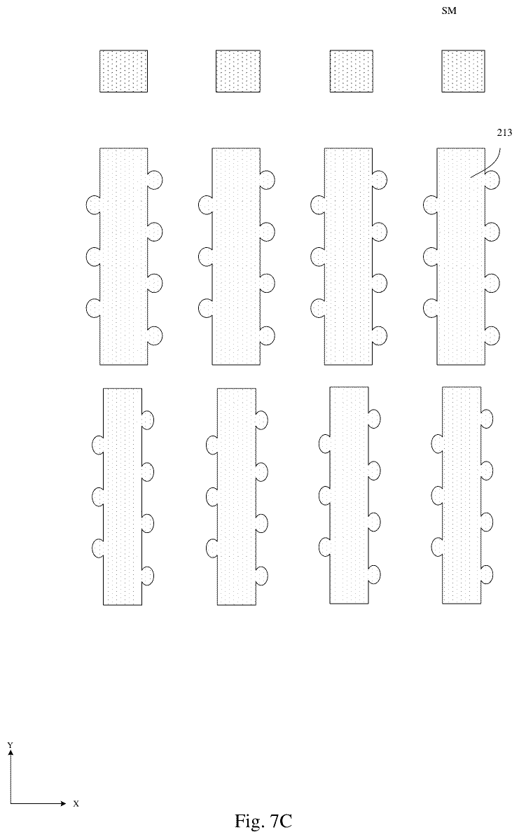

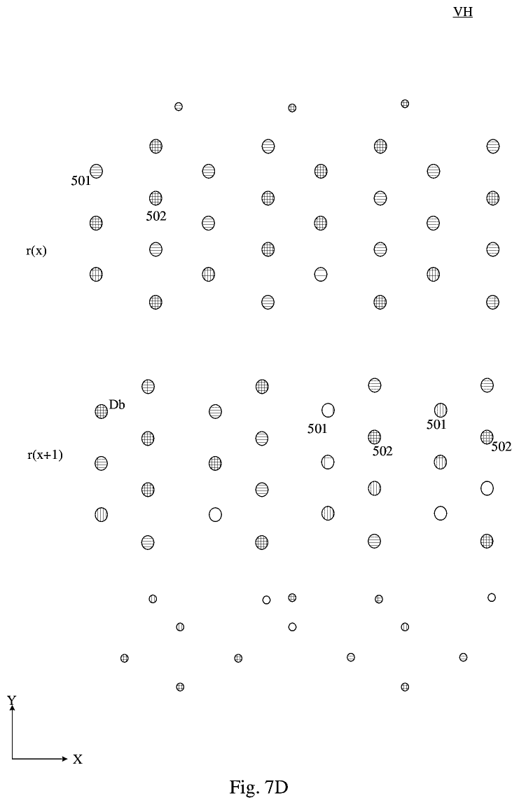

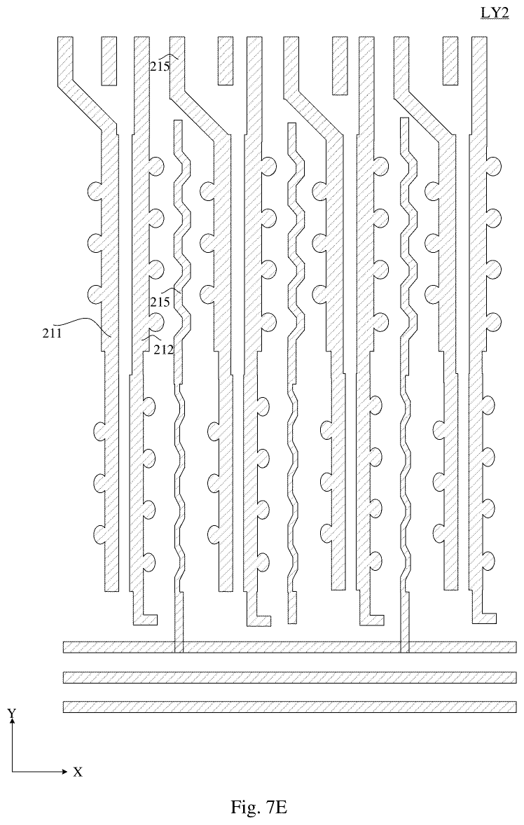

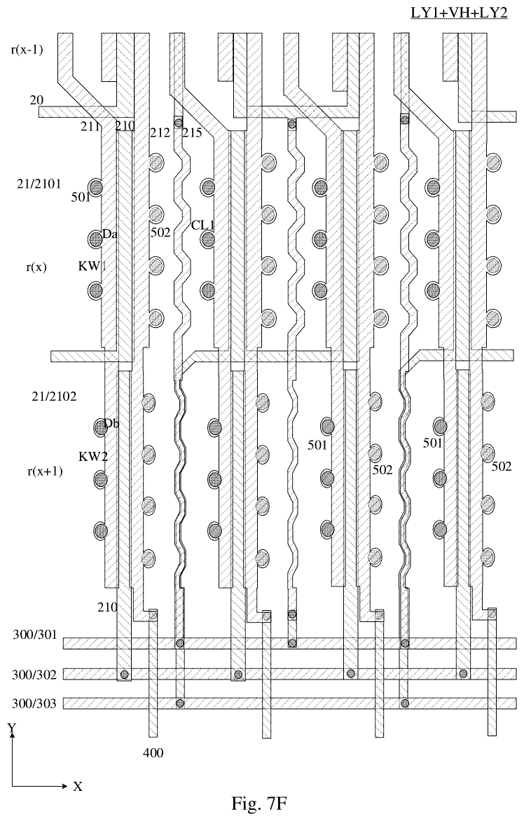

FIG. 7A is a schematic diagram of an array substrate according to an embodiment of the present disclosure. FIGS. 7B-7E are schematic diagrams of a single layer of the array substrate shown in FIG. 7A. FIG. 7F is a schematic diagram of a lamination structure of the array substrate shown in FIG. 7A. As shown in FIG. 7A, according to the array substrate 1002 provided in the embodiments of the present disclosure, a straight line, where the line CL1 connecting centers of one source via hole 501 and one drain via hole 502 which are located between the channel regions 2130 of two adjacent selection driving transistors in the same row and closest to each other is located, does not intersect with a source via hole 501 and a drain via hole 502 in an adjacent row, and is located between the source via hole 501 and the drain via hole 502 of the selection driving transistor 21 in the adjacent row.

As shown in FIG. 7A, the data selector circuit 20 includes two rows of selection driving transistors 21, i.e., r(x) rows of selection driving transistors 21 and r(x+1) rows of selection driving transistors 21.

As shown in FIG. 7A, a straight line, where the line CL1 connecting centers of one source via hole 501 and one drain via hole 502 which are located between the channel regions 2130 of two adjacent selection driving transistors in the r(x) row and closest to each other is located, does not intersect with the source via hole 501 and the drain via hole 502 of the selection driving transistor 21 of the r(x+1) row, and are located between the source via hole 501 and the drain via hole 502 of the selection driving transistor 21 in the r(x+1) row.

FIG. 7A does not show all the structures of the selection driving transistor 21 of r(x−1) row, and the structure of the selection driving transistor 21 of the r(x−1) row may refer to the structure of the selection driving transistor 21 in r(x+1) row. As shown in FIG. 7A, in two adjacent rows of data selector circuits 20, the maximum sizes of the two data selector circuits 20 in different rows in the row direction X are different.

As shown in FIG. 7A, in the r(x) row and the r(x+1) row data selector circuit 20, the maximum sizes of the data selector circuits 20 located in the r(X) row and in the r(x+1) row is different in the row direction X.

As shown in FIG. 7A, in the r(x) row and the r(x+1) row data selector circuits 20, the maximum size Da of the data selector circuit 20 in the row direction X of the r(x) row is greater than the maximum size Db of the data selector circuit 20 in the row direction X of the r(x+1) row. For example, the maximum size Da shown in FIG. 7A is the maximum size at the position of the data selector circuit 20 passing through the source via hole 501 in the r(x) row, and the maximum size Db shown in FIG. 7A is the maximum size of the position of the data selector circuit 20 passing through the source via hole 501 in the r(x+1) row. Certainly, the maximum size Da may also be the maximum size of the position of the data selector circuit 20 passing through the drain via hole 502 in the r(x) row, and the maximum size Db may also be the maximum size of the position of the data selector circuit 20 passing through the drain via hole 502 in the r(x+1) row.

As shown in FIG. 7A, the control signal line 300 includes a control signal line 301, a control signal line 302, and a control signal line 303.

As shown in FIG. 7A, the wiring 215 is connected to the control signal line 301, the gate electrode 210 of the data selector circuit 20 in the r(x) row is connected to the control signal line 303, and the gate electrode 210 of the data selector circuit 20 in the r(x+1) row is connected to the control signal line 302.

Because the data selector circuits 20 in different rows are connected to different control signal lines 300, different data lines may be connected, and different data lines may be used to sub-pixels correspondingly emitting different colors of light, so that different widths may be set for data selector circuits 20 in different rows. That is, in two adjacent rows of data selector circuits 20, different rows of data selector circuits 20 have different maximum sizes in the row direction X. Since the maximum sizes of the data selector circuits 20 in the row direction X are different, the channel widths of the data selector circuits 20 in different rows are different.

FIG. 7A further shows an input signal line 401, and the input signal line 401 is connected to the drain electrode 212.

For example, referring to FIG. 2 and FIG. 7A, according to the array substrate provided by the embodiments of the present disclosure, the data selector circuit 20 includes four control signal lines 300 extending in the row direction X, the four control signal lines 300 are respectively connected to the gate electrodes 210 of the corresponding selection driving transistors 21 in the plurality of selection driving transistors 21, and the input signal lines 400 are connected to the source electrodes 211 or the drain electrodes 212 of the corresponding selection driving transistors 21 in the plurality of selection driving transistors 21.

For example, as shown in FIG. 7A, according to the array substrate provided by the embodiments of the present disclosure, the plurality of selection driving transistors 21 include a first selection driving transistor 2101 and a second selection driving transistor 2102, the first selection driving transistor 2101 and the second selection driving transistor 2102 are respectively connected to different control signal lines 300, and the maximum size of the first selection driving transistor 2101 in the row direction X is different from the maximum size of the second selection driving transistor 2102 in the row direction X. For example, as shown in FIG. 7A, the maximum size of the first selection driving transistor 2101 in the row direction X is greater than the maximum size of the second selection driving transistor 2102 in the row direction X. For example, as shown in FIG. 7A, the first selection driving transistor 2101 is further away from the control signal line 300 than the second selection driving transistor 2102, that is, the first selection driving transistor 2101 is closer to the display region than the second selection driving transistor 2102.

FIG. 7B shows a conductive pattern layer LY1, the conductive pattern layer LY 1 includes a gate electrode 210 and a wiring 215. FIG. 7C shows an active layer SM, the active layer SM includes a semiconductor layer 213. FIG. 7D shows a via hole VH, the via hole VH includes a source via hole 501 and a drain via hole 502. FIG. 7E shows a conductive pattern layer LY2, the conductive pattern layer LY 2 includes a source electrode 211, a drain electrode 212, and a wiring 215. FIG. 7F shows a lamination schematic diagram of the conductive pattern layer LY1, the via hole VH, and the conductive pattern layer LY2.

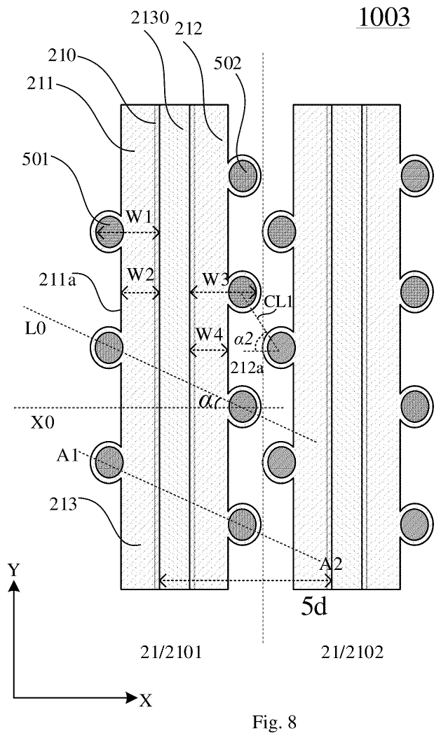

FIG. 8 is a schematic diagram of an array substrate according to an embodiment of the present disclosure. As shown in FIG. 8, according to the array substrate 1003 provided in the embodiments of the present disclosure, the wiring 215 located in the conductive pattern layer LY2 is not disposed between the adjacent selection driving transistors 21, and the wiring 215 is disposed in other conductive pattern layers. As shown in FIG. 8, p=5d.

As shown in FIG. 8, the included angle α2 between the row direction X and the line CL1 connecting centers of one source via hole 501 and one drain via hole 502 closest to each other and located between the channel regions 2130 of two adjacent selection driving transistors in the same row is greater than the included angle α between the row direction X and the line L0 connecting centers of any one source via hole 502 and one drain via hole 502 closest thereto of the same selection driving transistor 21.

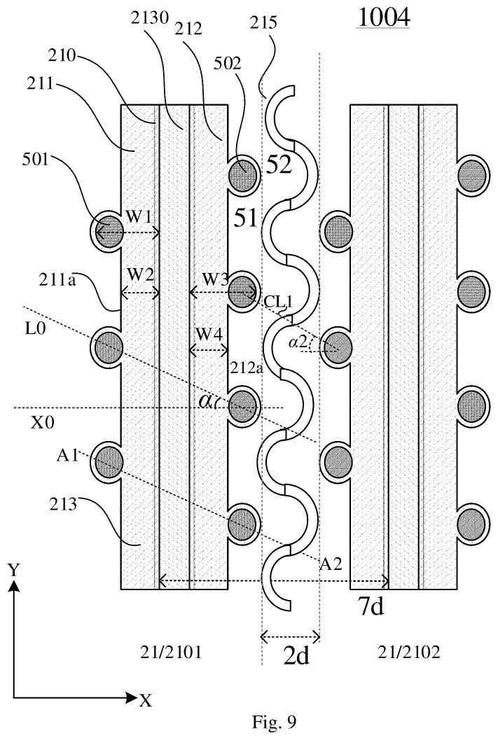

FIG. 9 is a schematic diagram of an array substrate according to an embodiment of the present disclosure. As shown in FIG. 9, according to the array substrate 1004 provided in the embodiments of the present disclosure, the wiring 215 between adjacent selection driving transistors 21 is wavy, and the wiring 215 is located in the conductive pattern layer LY2. The sum of the maximum dimensions occupied by the first portion 51 and the second portion 52 in the wiring 215 in the direction X is 2d. As shown in FIG. 9, p=7d. In other embodiments, the dimension occupied by the wiring 215 in the row direction X is d, and in this case, p=6d, and the wiring 215 may be disposed in layers different from that of the source electrode 211 and the drain electrode 212.

As shown in FIG. 9, the included angle α2 between the row direction X and the line CL1 connecting centers of one source via hole 501 and one drain via hole 502 closest to each other and between the channel regions 2130 of two adjacent selection driving transistors in the same row is greater than the included angle α between the row direction X and the line L0 connecting centers of any one source via hole 501 and one drain via hole 502 closest thereto of the same selection driving transistor 21.

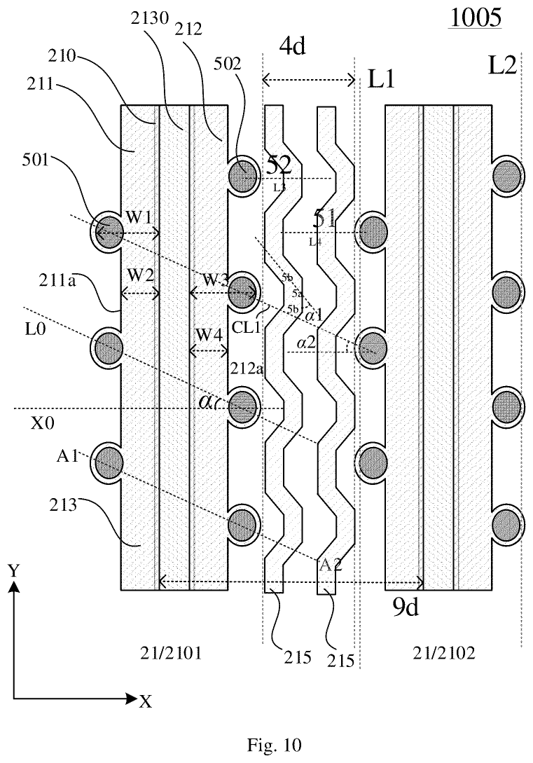

FIG. 10 is a schematic diagram of an array substrate according to an embodiment of the present disclosure. As shown in FIG. 10, according to the array substrate 1005 provided in the embodiments of the present disclosure, the wiring 215 between adjacent selection driving transistors 21 is in a broken line shape, the wiring 215 is located in the conductive pattern layer LY2, and two wirings 215 are provided. The sum of the maximum sizes occupied by the two wirings 215 in the direction X is 4d. As shown in FIG. 10, p=9d.

As shown in FIG. 10, the included angle α2 between the row direction X and the line CL1 connecting centers of one source via hole 501 and one drain via hole 502 closest to each other and between the channel regions 2130 of two adjacent selection driving transistors in the same row is equal to the included angle α between the row direction X and the line L0 connecting centers of any one source via hole 501 and one drain via hole 502 closest thereto of the same selection driving transistor 21.

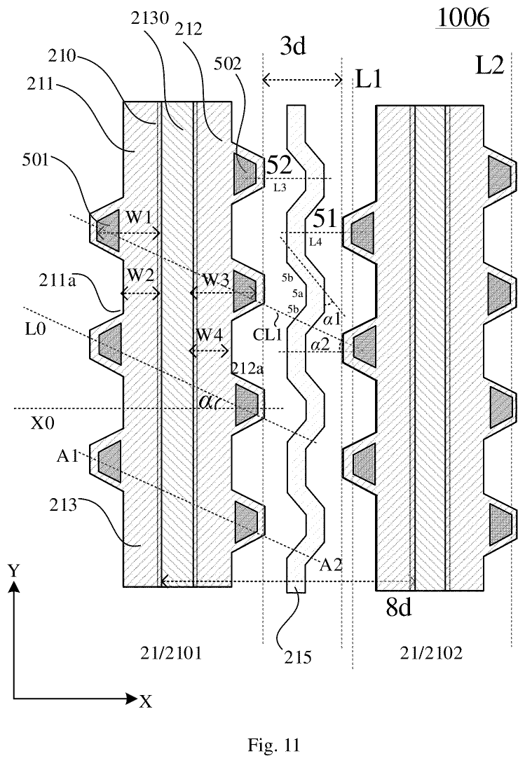

FIG. 11 is a schematic diagram of an array substrate according to an embodiment of the present disclosure. As shown in FIG. 11, according to the array substrate 1006 provided in the embodiments of the present disclosure, the shape of the connecting portion 2111 of the source electrode 211 is adjusted from a circle or an ellipse to a trapezoid. The main body portion 2110 of the source electrode 211 is also in a strip shape. The shape of the connecting portion 2121 of the drain electrode 212 is adjusted from a circle or an ellipse to a trapezoid. The main body portion 2120 of the drain electrode 212 is also strip-shaped. Correspondingly, the shape of a portion of the semiconductor layer 213 for connecting to the source electrode and the drain electrode is also adjusted to be trapezoidal, and correspondingly, the shape of the source via hole and the shape of the drain via hole may also be adjusted from a circle or an ellipse to a trapezoid, which is beneficial to maintaining the spacing uniformity between the components.

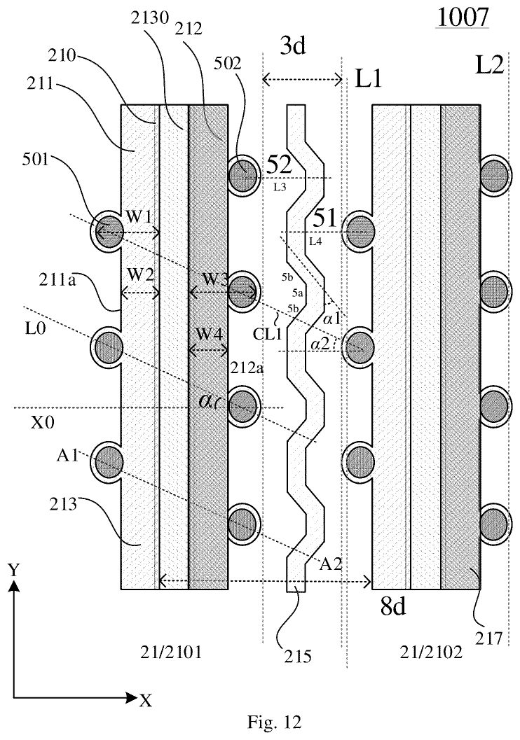

FIG. 12 is a schematic diagram of an array substrate according to an embodiment of the present disclosure. For example, as shown in FIG. 12, according to the array substrate 1007 provided in the embodiments of the present disclosure, the array substrate further includes a floating metal bar 218 located on a side of the source electrode 211 or the drain electrode 212 of the selection driving transistor 21 away from the semiconductor layer 213. The floating metal strip 218 plays a shielding role, and the floating metal bar 218 is provided to avoid electrostatic damage to the circuit on the array substrate.

For example, as shown in FIG. 12, the orthographic projection of the floating metal strip 218 on the base substrate covers the orthographic projection of the main body portion 2120 of the drain electrode 212 on the base substrate.

For example, as shown in FIG. 12, the orthographic projection of the floating metal strip 218 on the base substrate does not cover the orthographic projection of the connecting portion 2121 of the drain electrode 212 on the base substrate.

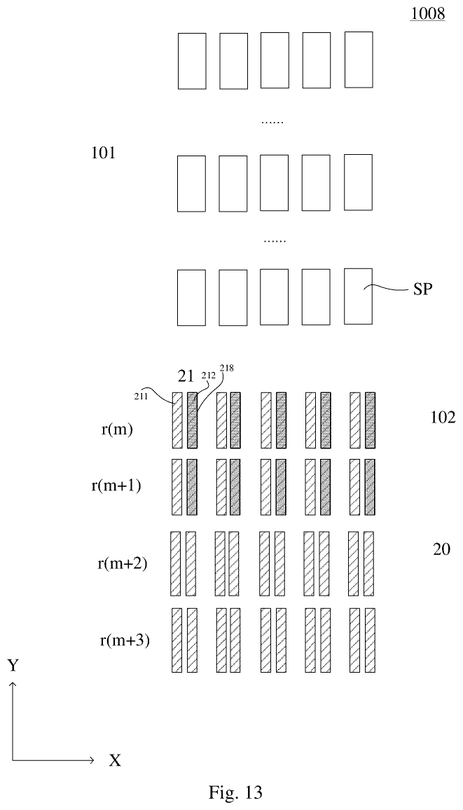

FIG. 13 is a schematic diagram of an array substrate according to an embodiment of the present disclosure. For example, as shown in FIG. 13, according to the array substrate 1008 provided in the embodiments of the present disclosure, the orthographic projection of the floating metal strip 218 on the base substrate covers the orthographic projection of the drain electrodes 212 of the two rows of selection driving transistors 21 close to the display area 101 on the base substrate, and the orthographic projection of the floating metal strip 218 on the base substrate does not cover the orthographic projection of the drain electrodes 212 of the two rows of selection driving transistors 21 away from the display region 101 on the base substrate. FIG. 13 shows four rows of selection driving transistors 21, in other embodiments, may also include more rows of selection driving transistors 21. In some other embodiments of the present disclosure, the orthographic projection of the floating metal bar 218 on the base substrate may only cover the orthographic projection of the drain electrodes 212 of the selection driving transistor 21 in one row close to the display region 101 on the base substrate. That is, in the embodiments of the present disclosure, the orthographic projection of the floating metal strip 218 on the base substrate covers the orthographic projection of the drain electrodes 212 of the selection driving transistors 21, which are in at least one row close to the display region 101 in the data selector circuit 20, on the base substrate, without covering the orthographic projection of the drain electrodes 212 of the selection driving transistors 21, which are in at least one row of the data selector circuit 20 away from the display area 101, on the base substrate.

For example, as shown in FIG. 13, the array substrate 1008 includes four rows, i.e., r(m) row, r(m+1) row, r(m+2) row, and r(m+3) row, wherein m is greater than or equal to 1. For example, as shown in FIG. 13, the orthographic projection of the floating metal strips 218 on the base substrate covers the orthographic projection of the drain electrodes 212 of the selection driving transistors 21 in the r(m) row and the r(m+1) row on the base substrate, without covering the orthographic projection of the drain electrodes 212 of the driving transistors 21 in the r(m+2) row and the r(m+3) row on the base substrate.

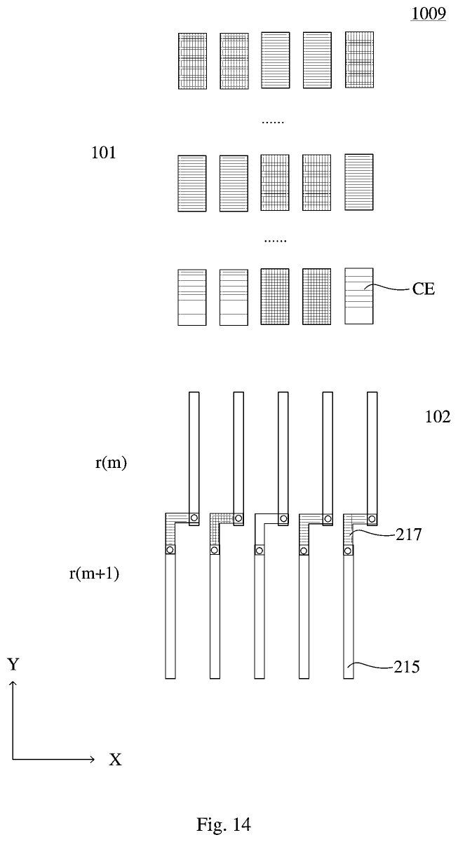

FIG. 14 is a schematic diagram of an array substrate according to an embodiment of the present disclosure. For example, according to the array substrate 1009 provided by the embodiments of the present disclosure, the array substrate 1009 further includes a common electrode CE located at different layers with the source electrode 211 and the drain electrode 212, the data selector circuit 20 includes a plurality of rows of selection driving transistors 21, and the wirings 215 between the selection driving transistors 21 in different rows are connected by a lead 217 formed by the metal on the same layer as the common electrode. FIG. 14 shows two rows of driving transistors 21, the driving transistors 21 of r(m+1) row showing only the wiring 215 located between adjacent drive transistors 21. For the driving transistor 21 of the r(m) row, a portion connected to the wiring 215 between the driving transistors 21 in the r(m+1) row may be a source electrode, a drain electrode, or other conductive structures of the driving transistor 21. For example, m is greater than or equal to 1.

For example, as shown in FIG. 14, the floating metal strip 218 and the common electrode CE are located in the same layer.

In the embodiments of the present disclosure, the components located in the same layer are formed by the same patterning process.

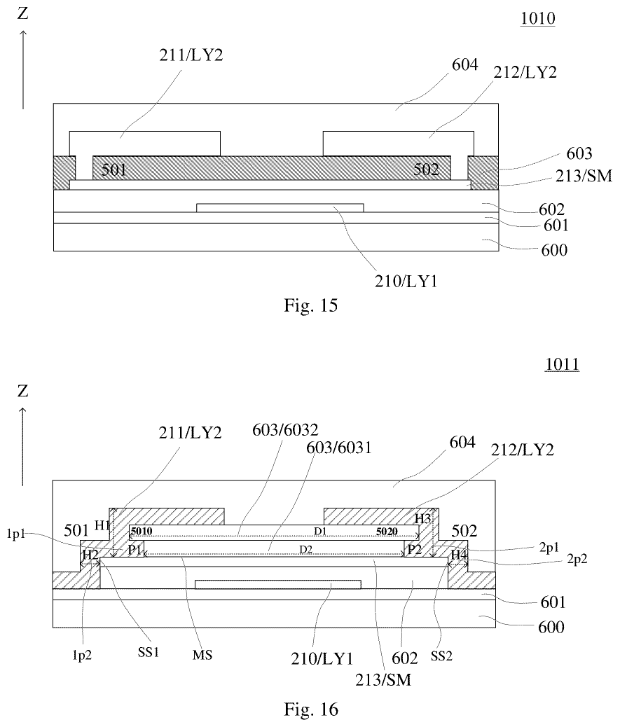

FIG. 15 is a schematic diagram of an array substrate according to an embodiment of the present disclosure. For example, according to the array substrate 1010 provided in the embodiments of the present disclosure, the source via hole 501 is disposed on the side of the source electrode 211 away from the drain electrode 212, and the drain via hole 502 is disposed on the side of the drain electrode 212 away from the source electrode 211. That is, both the source via hole 501 and the drain via hole 502 are disposed on the outer side to facilitate the improvement of the PPI of the display panel.

FIG. 16 is a schematic diagram of an array substrate according to an embodiment of the present disclosure. For example, according to the array substrate 1011 provided by the embodiments of the present disclosure, a first portion 1p1 of the source electrode 211 of the selection driving transistor 21 is in contact with a portion of the main surface MS of the semiconductor layer 213, a second portion 1p2 of the source electrode 211 of the selection driving transistor 21 is in contact with the side surface SS1 of the semiconductor layer 213, a first portion 2p1 of the drain electrode 212 of the selection driving transistor 21 is in contact with a portion of the main surface MS of the semiconductor layer 213, a second portion 2p2 of the drain electrode 212 of the selection driving transistor 21 is in contact with the side surface SS2 of the semiconductor layer 213. The second portion 1p2 of the source electrode 211 includes a first protrusion P1, the second portion 2p2 of the drain electrode 212 includes a second protrusion P2, the source via hole 501 includes a source semi-via hole 5010, and the source semi-via hole 5010 penetrates through a portion of the interlayer insulation layer 603; the drain via hole 502 includes a drain semi-via hole 5020, and the drain semi-via hole 5020 penetrates through a portion of the interlayer insulation layer 603. The first protrusion P1 is closer to the semiconductor layer 213 than a portion of the source electrode 211 in the source semi-via hole 5010; the second protrusion P2 is closer to the semiconductor layer 213 than a portion of the drain electrode 212 in the drain semi-via hole 5020. The first protrusion P1 and the second protrusion P2 are respectively connected to the semiconductor layer 213. The spacing D1 between the first protrusion P1 and the second protrusion P2 is smaller than the spacing D2 between the source semi-via hole 5010 and the drain semi-via hole 5020.

As shown in FIG. 16, the source semi-via hole 5010 is disposed such that the contact area between the source electrode 211 and the semiconductor layer 213 is increased. Due to the arrangement of the drain semi-via hole 5010, the contact area between the drain electrode 211 and the semiconductor layer 213 is increased.

For example, in the dry etching process of the via hole of the interlayer insulating layer 603, after etching to the semiconductor layer 213, the etching cannot be continued downwards, the etching gas etches the portion of the interlayer insulating layer 603 close to the semiconductor layer 213 to the inner side, and then the first protrusion P1 and the second protrusion P2 are formed in subsequent steps to increase the contact area between the source electrode 211 and the semiconductor layer 213, and the contact area between the drain electrode 211 and the semiconductor layer 213.

As shown in FIG. 16, the interlayer insulating layer 603 is located between the semiconductor layer 213, the source electrode 211, and the drain electrode 211. The interlayer insulating layer 603 includes an insulating sub-layer 6031 and an insulating sub-layer 6032, the insulating sub-layer 6031 is closer to the base substrate 600 than the insulating sub-layer 6032, and the material of the insulating sub-layer 6031 and the material of the insulating sub-layer 6032 are different. Certainly, the interlayer insulating layer 603 may also be of an integrated structure, or a semi-via hole may also be formed.

For example, as shown in FIG. 16, according to the array substrate provided by the embodiments of the present disclosure, the size H1 of the first portion 1p1 of the source electrode 211 in the direction perpendicular to the base substrate 600 (the direction Z) is greater than the size H2 of the second portion 1p2 of the source electrode 211 of the selection driving transistor 21 in the row direction X; the dimension H3 of the first portion 2p1 of the drain electrode 212 in the direction perpendicular to the base substrate 600 (the direction Z) is greater than the dimension H4 of the second portion 2p2 of the drain electrode 212 of the selection driving transistor 21 in the row direction X.

For example, as shown in FIG. 16, according to the array substrate provided by the embodiments of the present disclosure, the pattern shape of the gate insulating layer 602 is the same as the pattern shape of the semiconductor layer 213. As shown in FIG. 16, the source electrode 211 is in contact with the side surface of the gate insulating layer 602, and the drain electrode 212 is in contact with the side surface of the insulating layer 602.

For example, as shown in FIG. 16, the source electrode 211 is in contact with the surface of the buffer layer 601 away from the base substrate 600, and the drain electrode 212 is in contact with the surface of the buffer layer 601 away from the base substrate 600.

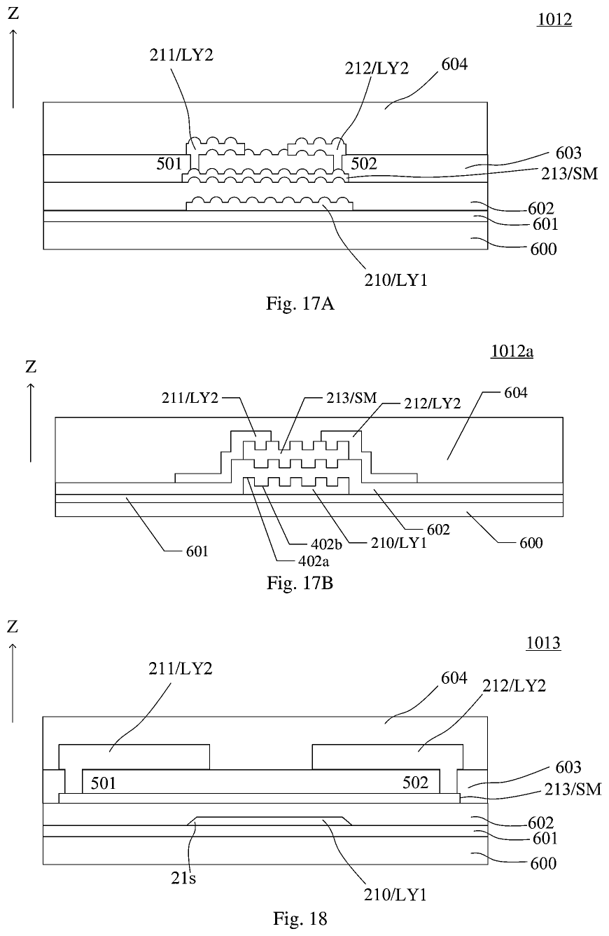

FIG. 17A is a schematic diagram of an array substrate according to an embodiment of the present disclosure. For example, according to the array substrate 1012 provided by the embodiments of the present disclosure, the surface of the side of the semiconductor layer 213 away from the gate electrode 210 has a concave-convex structure, and at least part of the subsequent structure is conformally formed on the semiconductor layer 213. The semiconductor layer 213 has a concave-convex structure, which is beneficial to improving the reliability of the transistor. The semiconductor layer 213 has a concave-convex structure, so that the semiconductor layer 213 has a larger heat dissipation area, which can effectively avoid the reduction of electron mobility caused by thermal deformation, reduce the driving force, avoid the positive shift of the photo bias temperature stress (PBTPS) curve (C-V curve), keep the characteristic stability of the transistor, and effectively improve the uniformity of the semiconductor layer 213. On the other hand, since the semiconductor layer 213 has an uneven non-flat surface, the transistor can occupy a small area, thereby reducing the frame of the display panel.

As shown in FIG. 17A, the surface of the gate electrode 210 away from the base substrate 600 has a concave-convex structure, so that the surface of the gate insulating layer 602 away from the base substrate 600 has a concave-convex structure, so that the surface of the side of the semiconductor layer 213 away from the gate electrode 210 has a concave-convex structure.

Certainly, in other embodiments, the surface of the gate electrode 210 away from the base substrate 600 may not have a concave-convex structure, the source electrode 211 and the drain electrode 212 may not have a concave-convex structure, and only the semiconductor layer 213 has a concave-convex structure.

FIG. 17B is a schematic diagram of an array substrate provided by an embodiment of the present disclosure. For example, compared with the array substrate 1012 shown in FIG. 17A, the surface of the source electrode 211 and the drain electrode 212 away from the base substrate 600 in the array substrate 1012 shown in FIG. 17B does not have a concave-convex structure.

For example, as shown in FIG. 4, FIG. 8 to FIG. 11, FIG. 12, FIG. 15, and FIG. 16, according to the array substrate provided by the embodiments of the disclosure, the gate electrode 210 is partially overlapped with the source electrode 211 and the drain electrode 212, respectively, and the overlapping sizes of the gate electrode 210 with the source electrode 211 and the drain electrode 212 are less than 1 μm in the row direction X.

FIG. 18 is a schematic diagram of an array substrate according to an embodiment of the present disclosure. For example, according to the array substrate 1013 provided by the embodiments of the present disclosure, the edge of the gate electrode 210 includes a slope portion 21s, and the overlapping size is greater than the size of the slope portion 21s in the row direction X. That is, the orthographic projection of the source electrode 211 on the base substrate overlaps at least the orthographic projection of the slope portion 21s at the edge of the gate electrode 210 on the base substrate, and the orthographic projection of the drain electrode 212 on the base substrate overlaps at least the orthographic projection of the slope portion 21s at the edge of the gate electrode 210 on the base substrate.

As shown in FIGS. 15-18, an insulating layer 604 is disposed on the conductive pattern layer LY2

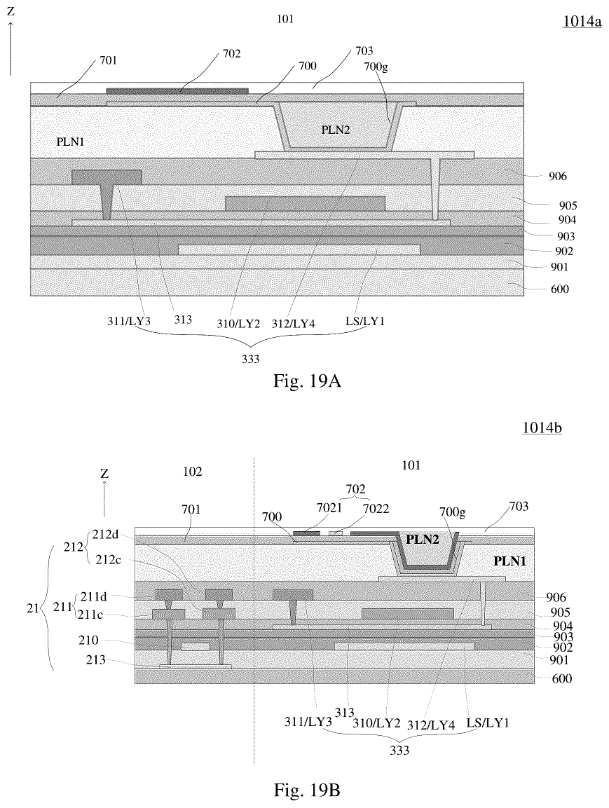

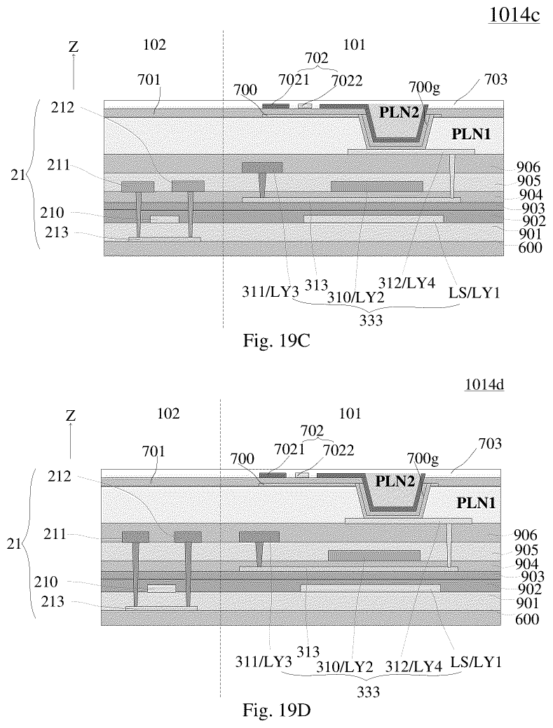

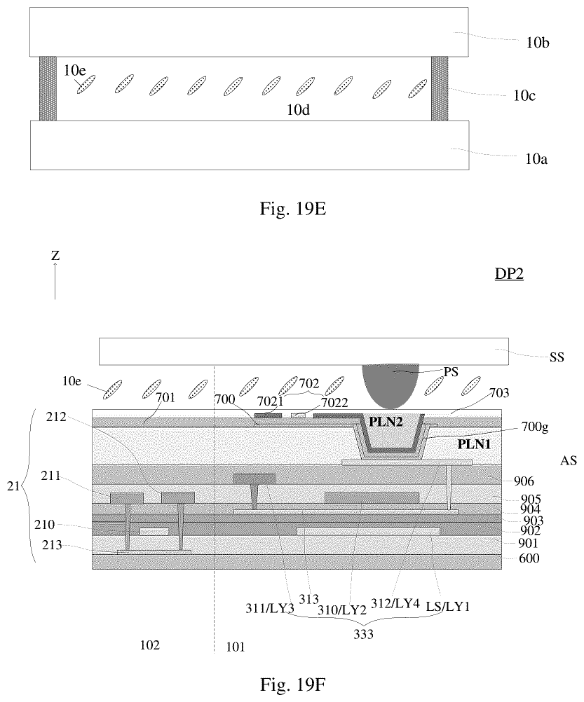

FIG. 19A is a schematic diagram of an array substrate according to an embodiment of the present disclosure. FIG. 19A shows an array substrate 1014a. FIG. 19B is a schematic diagram of an array substrate provided by an embodiment of the present disclosure. FIG. 19B illustrates an array substrate 1014b. FIG. 19C shows a schematic diagram of an array substrate provided by an embodiment of the present disclosure. FIG. 19C shows an array substrate 1014c. FIG. 19D is a schematic diagram of an array substrate provided by an embodiment of the present disclosure. FIG. 19D shows an array substrate 1014d.

For example, according to the array substrate 1014a-1014d provided by the embodiments of the present disclosure, the array substrate 1014a further includes a switching transistor 333 located in the display region 101, and the switching transistor 333 includes a light shielding layer LS that shields the channel region 3130 of the switching transistor 333. Referring to FIG. 6, FIG. 15 to FIG. 19D, the gate electrode 210 of the selection driving transistor 21 and the light-shielding layer LS of the display region 101 are located in the same layer.

For example, as shown in FIGS. 19A-19D, the display region 101 includes a switching transistor 333, and the material of the semiconductor layer 313 of the switching transistor 333 includes an oxide semiconductor material. For example, the oxide semiconductor material includes indium gallium zinc oxide (IGZO), but is not limited thereto.

For example, according to the array substrate provided by the embodiments of the present disclosure, as shown in FIG. 6, FIG. 15 to FIG. 18, FIG. 19B to FIG. 19D, the selection driving transistor 21 is a bottom gate thin film transistor, as shown in FIG. 6, FIG. 15 to FIG. 19A, and FIG. 19C, the source electrode 211 and the drain electrode 212 of the selection driving transistor 21 and the gate electrode 310 of the switching transistor are located in the same layer and are formed of the same material.

For example, according to the array substrate provided by the embodiments of the present disclosure, as shown in FIG. 6, FIG. 15 to FIG. 19D, the selection driving transistor 21 of the data selector circuit 20 is a bottom gate thin film transistor, the switching transistor is a top gate thin film transistor, and the source electrode 211 and the drain electrode 212 of the selection driving transistor 21 and the gate electrode 310 of the switching transistor are located in the same layer and are formed of the same material.

For example, as shown in FIGS. 19A-19D, according to the array substrate provided by the embodiments of the present disclosure, the drain electrode 312 of the switching transistor and the source electrode 311 of the switching transistor have different materials and are located in different layers.

As shown in FIGS. 19A-19D, the material of the source electrode 311 of the switching transistor includes a metal, for example, including Ti and Al, and may be a structure of a Ti—Al—Ti three-layer metal laminate. As shown in FIGS. 19A-19D, the drain electrode 312 of the switching transistor 333 may employ a conductive metal oxide, for example, indium tin oxide (ITO) may be used, but is not limited thereto.

For example, as shown in FIG. 19A, according to the array substrate provided by the embodiments of the present disclosure, the material of the drain electrode 312 of the switching transistor 333 includes an indium tin oxide, and the material of the source electrode 211 of the switching transistor includes a Ti/Al/Ti laminated structure.

For example, as shown in FIGS. 19A-19D, the array substrate further includes a planarization layer PLN1 and a pixel electrode 700, and the pixel electrode 700 is connected to the drain electrode 312 through a via hole penetrating through the planarization layer PLN1.

For example, as shown in FIGS. 19A-19D, the array substrate further comprises a common electrode 702 and an insulating layer 701 located between the common electrode 702 and the pixel electrode 700. For example, the common electrode 702 may be a slit electrode, and a multi-dimensional electric field is formed between the common electrode 702 and the pixel electrode 700 to drive the liquid crystal in the liquid crystal cell between the array substrate and the counter substrate to rotate, thereby displaying.

For example, as shown in FIG. 19B, the source electrode 211 of the selection driving transistor 21 includes a first source electrode portion 211c and a second source electrode portion 211d, the first source electrode portion 211c and the gate electrode 310 of the switching transistor 333 are located in the same layer, and the second source electrode portion 211d and the source electrode 311 of the switching transistor are located in the same layer. The source electrode 211 includes two source electrode portions, which is beneficial to reducing the resistance of the source electrode 211.

For example, as shown in FIG. 19B, the drain electrode 212 of the selection driving transistor 21 includes a first drain electrode portion 212c and a second drain electrode portion 212d, the first drain electrode portion 212c and the gate electrode 310 of the switching transistor 333 are located in the same layer, and the second drain electrode portion 212d and the source electrode 311 of the switching transistor are located in the same layer. The drain electrode 212 includes two drain electrode portions, which is conducive to reducing the resistance of the drain electrode 212.

For example, as shown in FIG. 19D, the source electrode 211 and the drain electrode 212 of the selection driving transistor 21 and the source electrode 311 of the switching transistor 333 are located in the same layer and are formed of the same material.

For example, as shown in FIGS. 19B-19D, the common electrode 702 includes a first electrode portion 7021 and a second electrode portion 7021.

For example, as shown in FIGS. 19B-19D, in a direction parallel to the main surface of the base substrate 600, the common electrode 702 includes first electrode portions 7021 spaced apart from each other, and a second electrode portion 7022 between the first electrode portions 7021. For example, the material of the second electrode portion 7022 includes a conductive metal, for example, copper metal, molybdenum metal and other materials with light shielding performance and conductivity. The material of the first electrode parts 7021 includes transparent conductive materials, for example, conductive metal oxides, such as indium tin oxide. The second electrode part 7022 can reduce the crosstalk of light in different pixel areas to improve the light efficiency.

For example, as shown in FIGS. 19B-19D, the material of the drain electrode 312 of the switching transistor 333 may be a conductive metal oxide, such as indium tin oxide, and the common electrode 702 may include first electrode portions 7021 spaced apart from each other in a direction parallel to the main surface of the base substrate 600, and a second electrode portion 7022 between the first electrode portions 7021.

For example, the second electrode portion 7022 may shield the light, thereby reducing the cross color of light of different colors along the direction Z, and the second electrode portion 7022 may also function as a black matrix extending along the direction X, so that the black matrix extending along the direction X does not need to be manufactured in the process of forming the counter substrate, and it is only required to manufacture a black matrix extending along the direction Y that crosses the direction X in a direction parallel to the main surface of the base substrate 600. In the conventional process of making black matrix, the black matrix extending in the direction X and the direction Y are made in different processes, so that the process steps of forming the black matrix extending in the direction X on the counter substrate can be reduced.

For example, as shown in FIGS. 19A-19D, the array substrate further includes a planarization layer PLN2, and the planarization layer PLN2 is located in a groove 700g formed by the pixel electrode 700 to level up the groove 700g to facilitate improving the display effect.

For example, as shown in FIGS. 19A-19D, the array substrate further includes an insulating layer 703, the insulating layer 703 covers the common electrode 702, and the insulating layer 703 may be an alignment layer to align the liquid crystal molecules.

FIG. 19E is a schematic diagram of a display panel according to an embodiment of the present disclosure. The display panel DP1 includes an array substrate 10a and a counter substrate 10b, the array substrate 10a and the counter substrate 10b are oppositely disposed, the array substrate 10a and the counter substrate 10b are bonded together by a sealant 10c, and a liquid crystal cell 10d is formed therein, and the liquid crystal molecules 10e are disposed in the liquid crystal cell 10d. FIG. 19E illustrates the liquid crystal display panel as an example. Certainly, the display panel provided in the embodiments of the present disclosure may also be other types of display panels, for example, may be an organic light-emitting diode display panel.

FIG. 19F is a schematic cross-sectional view of a display panel according to at least one embodiment of the present disclosure. As shown in FIG. 19F, the display panel DP2 includes an array substrate AS and a counter substrate SS, the array substrate AS and the counter substrate SS are disposed opposite to each other, and the liquid crystal molecules 10e are disposed between the array substrate AS and the counter substrate SS. Spacers PS are disposed on the counter substrate SS to support the cell thickness.

As shown in FIG. 19F, the planarization layer PLN2 is located in the groove 700g formed by the pixel electrode 700 to level up the groove 700g, that is, the orthographic projection of the planarization layer PLN2 on the base substrate 600 overlaps the orthographic projection of the pixel electrode 700 on the base substrate 600, so as to avoid display defects such as light leakage and the like caused by the spacer PS scratching the display area in the process of aligning the array substrate AS and the counter substrate SS, thereby improving the display effect.

As shown in FIG. 19F, the orthographic projection of the planarization layer PLN2 on the base substrate 600 overlaps the orthographic projection of the groove 700g of the pixel electrode 700 on the base substrate 600. As shown in FIG. 19F, the orthographic projection of the spacer PS on the base substrate 600 overlaps the orthographic projection of the planarization layer PLN2 on the base substrate 600. As shown in FIG. 19F, the orthographic projection of the spacer PS on the base substrate 600 overlaps the orthographic projection of the groove 700g of the pixel electrode 700 on the base substrate 600.

For example, as shown in FIG. 19F, the orthographic projection of the spacer PS on the base substrate 600 completely falls within the orthographic projection of the planarization layer PLN2 on the base substrate 600.

As shown in FIGS. 19B-19D and 19F, the selection driving transistor 21 includes a gate electrode 210.

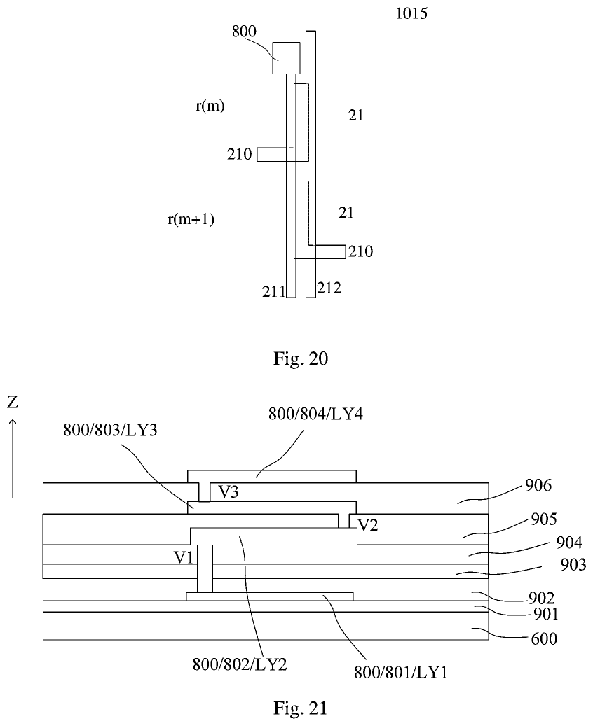

FIG. 20 is a schematic diagram of an array substrate according to an embodiment of the present disclosure. For example, according to the array substrate 1015 provided in the embodiments of the present disclosure, as shown in FIG. 20, the source electrodes 211 of the selection driving transistors 21 of the data selector circuit 20 located in different rows and in the same column are connected to the transferring structure 800. FIG. 20 shows an r(m) row selection driving transistor 21 and an r(m+1) row selection driving transistor 21. The r(m) row selection driving transistor 21 and the r(m+1) row selection driving transistor 21 are two adjacent rows of selection driving transistors 21. For example, as shown in FIG. 20, the drain electrodes 212 of the r(m) row and the r(m+1) row selection driving transistors 21 are connected, but it is not limited to this. For example, m is greater than or equal to 1.

FIG. 21 is a schematic diagram of a transferring structure in an array substrate provided by an embodiment of the present disclosure. As shown in FIG. 21, the transferring structure 800 includes a first conductive part 801, a second conductive part 802, a third conductive part 803 and a fourth conductive part 804. The first conductive part 801 is located in the same layer as the light shielding layer LS of the switching transistor 333, and both are located in the conductive pattern layer LY1. The second conductive part 802 and the gate electrode 310 of the switching transistor 333 are located in the same layer, and both are located in the conductive pattern layer LY2. The third conductive part 803 is located in the same layer as the source electrode 311 of the switching transistor, and both are located on the conductive pattern layer LY3. The fourth conductive portion 804 is located in the same layer as the drain electrode 312 of the switching transistor 333, and both are located on the conductive pattern layer LY4.

FIG. 19A to FIG. 19D, and FIG. 21 show that the insulating layer 901 to the insulating layer 906. As shown in FIG. 21, the second conductive portion 802 is connected to the first conductive portion 801 through a via hole V1, the third conductive portion 803 is connected to the second conductive portion 802 through a via hole V2, and the fourth conductive portion 804 is connected to the third conductive portion 803 through a via hole V3.

As shown in FIG. 21, the via hole V1 penetrates the insulating layer 902 to the insulating layer 904, the via hole V2 penetrates through the insulating layer 905, and the via hole V3 penetrates through the insulating layer 906.

For example, as shown in FIG. 4 and FIG. 11, according to the array substrate provided by the embodiments of the present disclosure, the pitch of the selection driving transistors 21 of the data selector circuit 20 in the row direction X is equal to 8d.

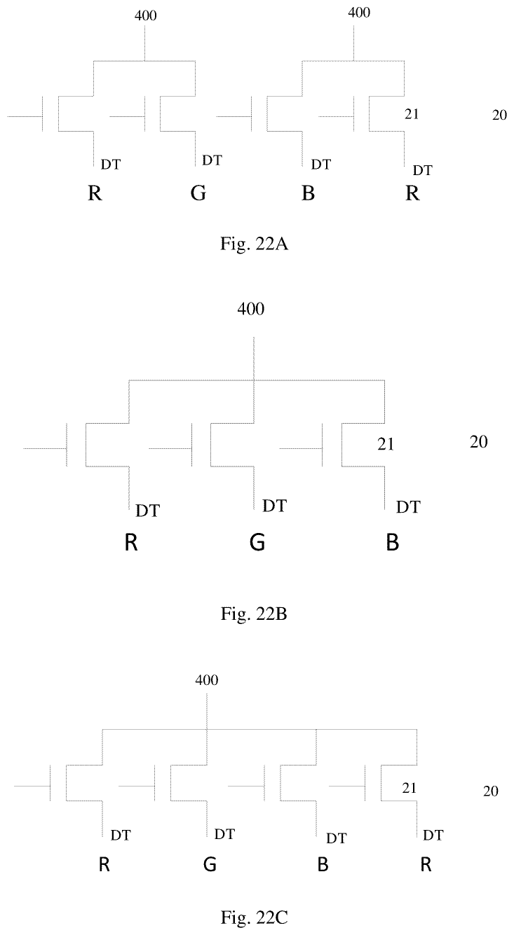

FIG. 22A is a schematic diagram of a data selector circuit in an array substrate according to an embodiment of the present disclosure. As shown in FIG. 22A, in the data selector circuit 20, one input signal line 400 corresponds to two data lines DT. One selection driving transistor 21 is connected to one data line. R, G, and B in the figures respectively represent a red sub-pixel, a green sub-pixel, and a blue sub-pixel.

FIG. 22B is a schematic diagram of a data selector circuit in an array substrate according to an embodiment of the present disclosure. As shown in FIG. 22B, in the data selector circuit 20, one input signal line 400 corresponds to three data lines DT. One selection driving transistor 21 is connected to one data line. R, G, and B in the figures respectively represent a red sub-pixel, a green sub-pixel, and a blue sub-pixel.

FIG. 22C is a schematic diagram of a data selector circuit in an array substrate according to an embodiment of the present disclosure. As shown in FIG. 22C, in the data selector circuit 20, one input signal line 400 corresponds to four data lines DT. One selection driving transistor 21 is connected to one data line. R, G, and B in the figures respectively represent a red sub-pixel, a green sub-pixel, and a blue sub-pixel.

For example, as shown in FIGS. 22A-22C, according to the array substrate provided by the embodiments of the present disclosure, the array substrate further includes a plurality of input signal lines 400, each input signal line 400 is connected to the N data lines through N selection driving transistors 21, and N is a positive integer greater than 1.

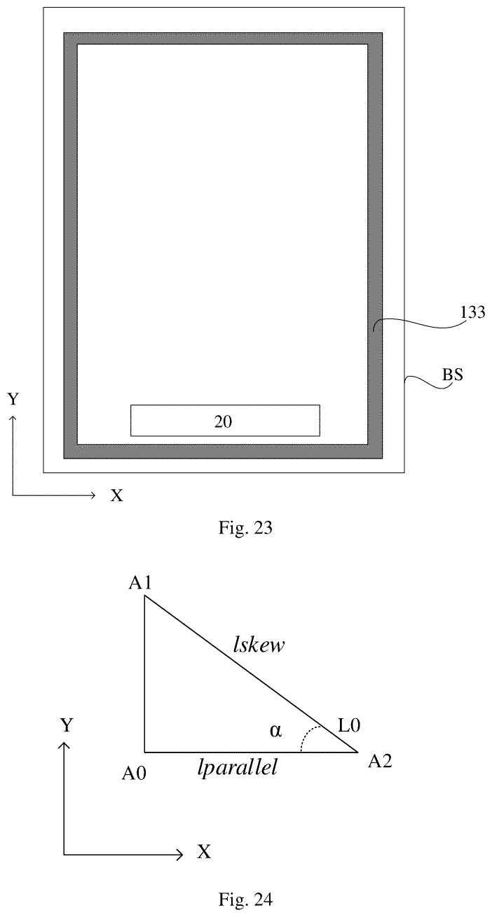

FIG. 23 is a schematic diagram of an array substrate according to an embodiment of the present disclosure. For example, as shown in FIG. 23, the array substrate includes a packaging area 133 provided with a sealant, and the data selector circuit 20 is disposed on an inner side of the packaging area 133. The sealant is disposed in the packaging area 133. For example, the packaging area 133 is an adhesive region of the array substrate and the counter substrate. The region on the inner side of the packaging area 133 is the region of the liquid crystal cell for holding the liquid crystal.

It should be noted that FIG. 19A and FIG. 23 are described by taking an array substrate as an array substrate of a liquid crystal display. In other embodiments, the array substrate may also be an array substrate of an OLED display.

An embodiment of the present disclosure provides a display, including any one of the above array substrates.

For example, the number of pixels per inch of the display is greater than 500 according to embodiments of the present disclosure

For example, the number of pixels per inch of the display is greater than 1000 according to embodiments of the present disclosure

For example, the display screen is 2.1 inches, the signal line includes 2160 gate lines and 2160×3 data lines, and the resolution is 1130 PPI. The pitch of adjacent select driving transistors is p.

For example, the diagonal length is 2.1 inches=5.334 cm, and the side length=3.77 cm.

As shown in FIG. 4, a wiring 215 is disposed in the same layer as the source electrode and the drain electrode between adjacent selection driving transistors, and the wiring 215 is a signal line having a broken line shape. The pitch p=8d of the adjacent selection driving transistors, d is the minimum critical dimension on the array substrate of the display screen, and is defined as the process resolution. For example, p=2.5 μm, but is not limited thereto.

For example, the side length of the display screen is 1, and the total number of the data lines is 3n.
(1) The resolution of the display screen is PPI, PPI=n/l.
(2) The width of the data selector circuit is smaller than the side length of the display screen, that is,

$$l \geq {k}_{2}^{′} \times \frac{3 n}{r} \times 8 d ,$$

wherein,

$$\frac{3 n}{r} \times 8 d$$

is equal to the width of the data selector circuit, 3n is the total number of data lines, 8d=the width d of the channel region+the width d of the main body portion of the source electrode+the width d of the source via hole+the distance d between the source via hole and the wiring+the width d of the wiring+the distance d between the drain via hole and the wiring+the drain via hole d+the width d of the main body portion of the drain electrode d; and according to (1) and (2), the following formula may be pushed out:

$$8 d \times PPI \leq {k}_{1} ,$$

where,

$${k}_{1} = \frac{1}{{k}_{2}^{′}} \times \frac{r}{3} , {k}_{2}^{′} \geq 1 ,$$

the spacing or the selection driving transistor is p, p=4d+xd, and the screen resolution is PPI.

For example, in some embodiments, the measured value p=21.5 μm, PPI=1130, p×PPI=0.9565=(p×PPI÷10000÷2.54), 1 foot (inch)=25400 μm, p×PPI≤k₁,

$${k}_{1} = \frac{1}{{k}_{2}^{′}} \times \frac{r}{3} ,$$

and according to designer experience, the row number r of the data selector circuit satisfies 1≤r≤8, 0.75≤k′₂≤1, and the actual design value is 0.78; then pushing out: 3.6≥k₁≥0.33, and further for example, 4≥k≥0.3.

For example, the frame height of the display panel is h, the number of the via holes is q, q is the sum of the number of the source via holes and the drain via holes, the number of rows of the data selector circuit is r, and the included angle between the row direction X and the line L0 connecting centers of any one source via hole 501 and one drain via hole 502 closest thereto of the same selection driving transistor 21 is a, and then h=k₂×r×(2q−1)×4d×tan α, 4d=the channel region d+the width d of the main body portion of the source electrode+the width d of the main body portion of the drain electrode+the width d of the via hole; the range of the proportionality coefficient k2 is: 0.9<k2<1.5; 30<α<60.

For example, according to the display provided by the embodiment of the present disclosure, the width of the wiring 215, the width of the source electrode 211 of the selective driving transistor 21, the width of the drain electrode 212 of the selective driving transistor 21, the diameter of the source via hole 501, and the diameter of the drain via hole 502 are approximately equal to the dimension d, and 1.5 microns≤d≤4 microns.

For example, according to the display provided by the embodiments of the present disclosure, the pitch of the selection driving transistors 21 of the data selector circuit 20 in the row direction X is equal to 8d, PPI×8D<K1, and 0.3≤K1≤4.

For example, according to the display provided by the embodiments of the present disclosure, the frame height of the display is h, the number of the source via holes 501 or the drain via holes 502 of one selection driving transistor 21 of the data selector circuit 20 is q, the row number of the driving transistors of the data selector circuit 20 is r, and the included angle between the row direction X and the line L0 connecting centers of any one source via hole 501 and one drain via hole 502 closest thereto of the same selection driving transistor 21 is a, where q, r, d, and α satisfy:

$$h = k 2 \times r \times ( 2 q - 1 ) \times 4 d \times tan α ,$$

where k2 is a proportionality coefficient, and 0.9<k2<1.5, 30<α<60.

For example, as shown in FIG. 4, FIG. 8 to FIG. 12, the influence of the included angle α between the row direction X and the line L0 connecting centers of any one source via hole 501 and one drain via hole 502 closest thereto of the same selection driving transistor 21 is as follows.

FIG. 24 shows that the length of the channel is lskew when the line L0 connecting centers of the source via hole and the drain via hole is obliquely disposed relative to the row direction X. In the case that the line L0 connecting centers of the source via hole and the drain via hole is parallel to the row direction X, the length of the channel is lparallel.

The position A1 and the position A2 in FIG. 24 may be regarded as the positions of the source via hole and the drain via hole, and the line A1-A2 may be regarded as the line L0 connecting centers of the source via hole and the drain via hole. The position A0 can be regarded as the position of the source via hole in the case where the line L0 connecting centers of the source via hole and the drain via hole is parallel to the row direction X.

The influence of the included angle α on the driving current of the selection driving transistor is as follows.

$${I}_{D} = \frac{W}{L} {μ}_{n} {C}_{0} [ ( {V}_{GS} - {V}_{TH} ) {V}_{DS} - \frac{1}{2} {V}_{DS}^{2} ] .$$

$$Saturation region : {I}_{D} = \frac{W}{2 L} {μ}_{n} {C}_{0} {( {V}_{GS} - {V}_{TH} )}^{2} . Linear region : {I}_{D} = \frac{W}{2 L} {μ}_{n} {C}_{0} ( {V}_{GS} - {V}_{TH} ) {V}_{DS} . Channel length ratio : \frac{{l}_{s k e w}}{{l}_{parallel}} = \frac{1}{cos α} . Current loss ratio : {R}_{I \_loss} = \frac{{I}_{{D}_{-} skew}}{{I}_{D\_parallel}} = \frac{\frac{W}{2 {l}_{skew}} {μ}_{n} {C}_{0} {( {V}_{GS} - {V}_{TH} )}^{2}}{\frac{W}{2 {l}_{parallel}} {μ}_{n} {C}_{0} {( {V}_{GS} - {V}_{TH} )}^{2}} = \frac{{l}_{parallel}}{{l}_{skew}} = cos α . 1 + {tan}^{2} α = \frac{1}{{cos}^{2} α} .$$

For example, the current loss ratio R_{I_loss} of the selection driving transistor 21 satisfies:

$${R}_{I\_loss} = cos α = \sqrt{\frac{1}{1 + \frac{{h}^{2}}{16 {k}_{2}^{2} {r}^{2} {{d}^{2} ( 2 q - 1 )}^{2}}}} ,$$

where R_{I_loss} is the current loss ratio, μₙ is the carrier mobility in the channel of the selection driving transistor, C₀ is the channel capacitance per unit area of the selection driving transistor, V_{GS} is the voltage difference between the source and the gate of the selection driving transistor, V_{TH} is the threshold voltage of the selection driving transistor, V_{DS} is the voltage difference between the source and the drain of the selection driving transistor, W is the channel width, L is the channel length, I_{D_skew} is the driving current in the case that the line L0 connecting centers of the source via hole and the drain via hole is inclined relative to the row direction X, and I_{D_parallel} is the driving current in the case that the line L0 connecting centers of the source via hole and the drain via hole is parallel to the row direction X.

Therefore, the smaller the process resolution d, the smaller the driving current loss of the selection driving transistor 21 is.

For example, the display may be an OLED display device or a liquid crystal display device.

For example, the display device may be any product or component having a display function, such as a television, a digital camera, a mobile phone, a watch, a tablet computer, a notebook computer, a navigator, etc. including the above-mentioned display device.

It should be noted that, for clarity, in the drawings for describing the embodiments of the present disclosure, the thickness of the layer or region is amplified. It will be appreciated that when an element such as a layer, film, region, or substrate is referred to as being “on” or “under” another element, the element may be “directly” on or “under” another element, or intervening elements may be present.

In the embodiment of the present disclosure, the source electrode and the drain electrode of the transistor refer to the two poles of the transistor except the gate electrode, and the source electrode and the drain electrode are relative and interchangeable.

In the embodiments of the present disclosure, the elements located in the same layer may be formed by the same patterning process. For example, the elements located in the same layer may be located on the surface of the same element away from the base substrate, but are not limited thereto.

In the embodiments of the present disclosure, the patterning or patterning process may only include a photolithography process, or include a photolithography process and an etching step, or may include other processes for forming a predetermined pattern, such as printing and inkjet. The photolithography process refers to processes such as film forming, exposure, development and the like, and patterns are formed by using photoresist, a mask plate, an exposure machine, and the like. The corresponding patterning process may be selected according to the structure formed in the embodiments of the present disclosure.

For example, in an embodiment of the present disclosure, the direction Z is a direction perpendicular to the main surface of the base substrate. The main surface of the base substrate is a surface for manufacturing various components. The direction X and the direction Y are directions parallel to the main surface of the base substrate. Direction X intersects direction Y. According to an embodiment of the present disclosure, the direction X and the direction Y are perpendicular to each other.

For example, the buffer layer 601, the insulating layer 601 to the insulating layer 604, the buffer layer 701, the insulating layer 901 to the insulating layer 906 are all made of an insulating material, for example, the insulating material comprises an inorganic insulating layer material, and the inorganic insulating layer material comprises at least one of silicon oxide, silicon nitride or silicon oxynitride. The buffer layer 703, the planarization layer PLN1, and the planarization layer PLN2 are all made of an insulating material, for example, the insulating material includes an organic insulating material, for example, the organic insulating material includes a resin, but is not limited thereto. The base substrate 600 may be made of materials such as glass and polyimide, but is not limited thereto.

For example, in the embodiments of the present disclosure, the conductive pattern layer LY1, the conductive pattern layer LY2, the conductive pattern layer LY3, and the conductive pattern layer LY4 are all made of a conductive material. For example, the conductive pattern layer LY1, the conductive pattern layer LY2, and the conductive pattern layer LY3 are all made of a metal material, and the conductive pattern layer LY4 is made of a conductive metal oxide. For example, the material of at least one of the conductive pattern layer LY1, the conductive pattern layer LY2, or the conductive pattern layer LY3 includes at least one of titanium (Ti) or aluminum (Al), and the material of at least one of the conductive pattern layer LY1, the conductive pattern layer LY2, or the conductive pattern layer LY3 includes molybdenum (Mo) or nickel (Ni). For example, the material of at least one of the conductive pattern layer LY1 or the conductive pattern layer LY2 includes molybdenum (Mo) or nickel (Ni), and the material of the conductive pattern layer LY3 includes at least one of titanium (Ti) or aluminum (Al). Certainly, the conductive pattern layer LY1, the conductive pattern layer LY2, and the conductive pattern layer LY3 may also adopt other suitable materials, which is not limited in the embodiments of the present disclosure.

For example, in the embodiments of the present disclosure, the pixel electrode 700 may be made of a transparent conductive material, and the transparent conductive material includes indium tin oxide, but is not limited thereto.

For example, in the embodiments of the present disclosure, the common electrode 702 may be made of a metal material, but is not limited thereto.

In the case of no conflict, the features in the same embodiment and different embodiments of the present disclosure may be combined with each other.

The foregoing is merely specific embodiments of the present disclosure, but the scope of protection of the present disclosure is not limited thereto, and any person skilled in the art may easily conceive of changing or replacing within the technical scope disclosed in the present disclosure, and should be covered within the protection scope of the present disclosure. Therefore, the protection scope of the present disclosure shall be subject to the protection scope of the claims.

1. An array substrate, comprising a display region and a peripheral region surrounding the display region, the peripheral region comprising a data selector circuit configured to provide a data signal to a data line, the data selector circuit comprising a plurality of selection driving transistors arranged in a row direction and a column direction, wherein
each of the selection driving transistors comprises a semiconductor layer, a source electrode and a drain electrode, the source electrode and the drain electrode both are strip-shaped, the source electrode and the drain electrode both extends in the column direction, a portion of the semiconductor layer between the source electrode and the drain electrode is formed as a channel region, the source electrode is connected to the semiconductor layer through a plurality of source via holes on a side of the source electrode away from the channel region, the drain electrode is connected to the semiconductor layer through a plurality of drain via holes on a side of the drain electrode away from the channel region,
a minimum distance between the channel region and an edge of the source via hole furthest from the channel region is greater than a minimum distance between the channel region and a portion of an outer edge of the source electrode between two source via holes, and a minimum distance between the channel region and an edge of the drain via hole furthest from the channel region is greater than a minimum distance between the channel region and a portion of an outer edge of the drain electrode between two drain via holes, an acute included angle is formed between the row direction and a line connecting centers of any one of the source via holes and any one of the drain via holes.

2. The array substrate according to claim 1, wherein an included angle between the row direction and a line connecting centers of any one of source via holes and one drain via hole closest thereto of a same selection driving transistor is in a range from 35 degrees to 55 degrees.

3. The array substrate according to claim 1, wherein points of a plurality of source via holes of a same selection driving transistor away from the channel region are located on a first straight line, points of a plurality of drain via holes of the same selection driving transistor away from the channel region are located on a second straight line, and the first straight line is approximately parallel to the second straight line and is approximately parallel to the column direction, a portion of the source electrode located between adjacent source via holes and a portion of the drain electrode located between adjacent drain via holes are located between the first straight line and the second straight line, and are not overlapped with the first straight line and the second straight line.

4. The array substrate according to claim 1, wherein the data selector circuit further comprises a wiring located between two adjacent selection driving transistors, the wiring extends in a zigzag manner along the column direction, the two adjacent selection driving transistors are respectively a first selection driving transistor and a second selection driving transistor, the wiring comprises a plurality of first portions closest to the channel region of the first selection driving transistor in the row direction, the wiring comprises a plurality of second parts closest to the channel region of the second selection driving transistor in the row direction, and in the column direction, the plurality of first portions and the plurality of second parts are alternately arranged, the plurality of drain via holes of the first selection driving transistor and the plurality of source via holes of the second selection driving transistor are located between the channel region of the first selection driving transistor and the channel region of the second selection driving transistor,
the plurality of drain via holes of the first selection driving transistor are in one-to-one correspondence with the plurality of second portions, and a line connecting centers of each of the drain via holes and the corresponding second portion is substantially parallel to the row direction,
the plurality of source via holes of the second selection driving transistor are in one-to-one correspondence with the plurality of first portions, and a line connecting centers of each of the source via holes and the corresponding first portion is substantially parallel to the row direction.

5. The array substrate according to claim 4, wherein the wiring includes a plurality of vertical straight-line segments substantially parallel to the column direction and arranged at intervals along the column direction, and inclined straight-line segments connecting adjacent vertical straight-line segments at an acute angle with respect to the row direction, and at least a portion of each vertical straight-line segment is the first portion or the second portion.

6. The array substrate according to claim 4, wherein any one of a width of the wiring, a width of the portion of the source electrode of the selection driving transistor between adjacent source via holes, a width of the portion of the drain electrode of the selection driving transistor between adjacent drain via holes, a diameter of the source via holes, or a diameter of the drain via holes is substantially equal to a dimension d, and 1.5 μm≤d≤4 μm,
wherein a pitch of the selection driving transistors of the data selector circuit in the row direction is equal to 8d.

7. The array substrate according to claim 6, wherein a minimum distance between the source via hole and the wiring, and a minimum distance between the drain via hole and the wiring are approximately equal to the dimension d, respectively.

8. The array substrate according to claim 5, wherein an included angle between an extending direction of the vertical straight-line segment and an extending direction of the inclined straight-line segment ranges from 35 degrees to 55 degrees, and is less than or equal to an included angle between the row direction and a line connecting centers of any one of the source via holes and one drain via hole closest thereto of a same selection driving transistor.

9. The array substrate according to claim 5, wherein a number of the inclined straight-line segments included in the wiring is greater than or equal to a sum of a number of the source via holes adjacent to the wiring and a number of the drain electrode via holes.

10. The array substrate according to claim 4, wherein the wiring and the source electrode and the drain electrode of the selection driving transistor are made of a same layer of metal thin film, and the metal thin film is a single-layer metal thin film or comprises a plurality of metal sub-layers.

11. The array substrate according to claim 4, wherein the wiring comprises at least one of a data line connected to the source electrode or the drain electrode of the selection driving transistor or a control signal connecting line connected to a gate electrode of the selection driving transistor.

12. The array substrate according to claim 4, further comprising a common electrode located at different layers with the source electrode and the drain electrode, wherein the data selector circuit comprises a plurality of rows of selection driving transistors, and wirings between the selection driving transistors in different rows are connected to a lead made of a metal on the same layer as the common electrode.

13. (canceled)

14. The array substrate according to claim 1, wherein the array substrate further comprises a plurality of input signal lines, each input signal line is connected to N data lines through N selection driving transistors, and N is a positive integer greater than 1.

15. The array substrate according to claim 5, wherein an included angle between the row direction and a line connecting centers of one source via hole and one drain via hole with minimum distance between the channel regions of two adjacent selection driving transistors in a same row is in a range from 35 degrees to 55 degrees,
wherein the included angle between the row direction and a line connecting centers of one source via hole and one drain via hole with minimum distance between the channel regions of two adjacent selection driving transistors in the same row is equal to an included angle between the row direction and a line connecting centers of any one of source via holes and one drain via hole closet thereto of a same selection driving transistor.

16. (canceled)

17. The array substrate according to claim 15, wherein a straight line, where a line connecting centers of one source via hole and one drain via hole with minimum distance between the channel regions of two adjacent selection driving transistors in a same row is located, intersect with the inclined straight-line segment and does not intersect with the vertical straight-line segment; or
wherein the straight line, where the line connecting centers of one source via hole and one drain via hole with minimum distance between the channel regions of two adjacent selection driving transistors in a same row is located, does not intersect with the source via hole and the drain via hole of the selection driving transistor in an adjacent row, and is located between the source via hole and the drain electrode via hole of the selection driving transistor in the adjacent row.

18. (canceled)

19. The array substrate according to claim 1, further comprising a first insulating layer and a second insulating layer, wherein the selection driving transistor further comprises a gate electrode located on a side of the semiconductor layer opposite to the source electrode and the drain electrode, the first insulating layer is provided between the gate electrode and the semiconductor layer, and the second insulating layer is located between the semiconductor layer, the source electrode and the drain electrode,
wherein a first portion of the source electrode of the selection driving transistor is in contact with a portion of a main surface of the semiconductor layer, and a second portion of the source electrode of the selection driving transistor is in contact with a side surface of the semiconductor layer;
a first portion of the drain electrode of the selection driving transistor is in contact with a portion of a main surface of the semiconductor layer, a second portion of the drain electrode of the selection driving transistor is in contact with a side surface of the semiconductor layer;
the first portion of the source electrode includes a first protrusion portion, the first portion of the drain electrode includes a second protrusion portion;
the source via hole includes a source semi-via-hole, and the source semi-via-hole penetrates through a portion of the second insulation layer;
the drain via hole includes a drain semi-via-hole, the drain semi-via-hole penetrates through a portion of the second insulating layer;
the first protrusion portion is closer to the semiconductor layer than a portion of the source electrode located in the source semi-via-hole;
the second protrusion portion is closer to the semiconductor layer than a portion of the drain electrode located in the drain semi-via-hole;
the first protrusion portion and the second protrusion portion are respectively connected to the semiconductor layer, and a distance between the first protrusion portion and the second protrusion portion is less than a distance between the source semi-via-hole and the drain semi-via-hole,
wherein a size of the first portion of the source electrode in the row direction is greater than a size of the second portion of the source electrode of the selection driving transistor in a direction perpendicular to the row direction and the column direction;
the size of the first portion of the drain electrode in the row direction is greater than the size of the second portion of the drain electrode of the selection driving transistor in the direction perpendicular to the row direction and the column direction.

20-21. (canceled)

22. The array substrate according to claim 19, wherein the first insulating layer has a pattern shape the same as that of the semiconductor layer,
wherein a surface at a side of the semiconductor layer away from the gate electrode has a concave-convex structure, and at least part of a structure is conformally formed on the concave-convex structure,
wherein the gate electrode overlaps the source electrode and the drain electrode portion, respectively, and an overlapping size of the gate electrode and the source electrode and the drain electrode is less than 1 micrometer in the row direction.

23-27. (canceled)

28. The array substrate according to claim 14, wherein the data selector circuit comprises four control signal lines extending in the row direction, the four control signal lines are respectively connected to the gate electrodes of the corresponding selection driving transistors in the plurality of selection driving transistors, and the input signal lines are connected to the source electrodes of the corresponding selection driving transistors in the plurality of selection driving transistors,
wherein the plurality of selection driving transistors comprises a first selection driving transistor and a second selection driving transistor, the first selection driving transistor and the second selection driving transistor are respectively connected to different control signal lines, and a maximum size of the first selection driving transistor in the row direction is different from a maximum size of the second selection driving transistor in the row direction.

29-36. (canceled)

37. A display, comprising the array substrate according to claim 1, wherein a number of pixels per inch of the display is greater than 500,
wherein a width of the wiring, a width of the source electrode of the selection drive transistor, a width of the drain electrode of the selection drive transistor, a diameter of the source via hole, a diameter of the drain via hole each are substantially equal to a dimension d, and 1.5 μm≤d≤4 μm.

38-41. (canceled)

42. The display according to claim 37, wherein a frame height of the display is h, a number of the source via holes or the drain via holes of one of the selection driving transistors of the data selector circuit is q, a row number of the driving transistors of the data selector circuit is r, and an included angle between the row direction and a line connecting centers of any one of the source via holes and one drain via hole closest thereto of a same selection driving transistor is α, where q, r, d, and α satisfy:
$$h = {k}_{2} \times r \times ( 2 q - 1 ) \times 4 d \times tan α ,$$
where k₂ is a proportionality coefficient, and 0.9<k₂<1.5, 30<α<60, and
wherein a current loss ratio R_{I_loss} of the selection driving transistor satisfies:
$${R}_{I\_loss} = cos α = \sqrt{\frac{1}{1 + \frac{{h}^{2}}{16 {k}_{2}^{2} {r}^{2} {{d}^{2} ( 2 q - 1 )}^{2}}}}$$
where R_{I_loss} is a current loss ratio.
